(19) United States
(12) Patent Application Publication
(10) Pub. No.: US 2006/0164533 A1
(43) Pub. Date: Jul. 27, 2006

(54) Electronic image sensor

(75) Inventors: Tzu-Chiang Hsieh, Freemont, CA (US); Calvin Chao, Cupertino, CA (US)

Correspondence Address: JOHN R. ROSS;TREX ENTERPRISES, 10455 PACIFIC CENTER CT, SAN DIEGO, CA, 92121, US

(73) Assignee: e-Phocus, Inc

(21) Appl. No.: 11/389,356

(22) Filed: Mar. 24, 2006

Related U.S. Application Data
(63) Continuation-in-part of application No. 10/921,387, filed on Aug. 18, 2004.
Application No. 10/921,387 is a continuation-in-part of application No. 10/229,953, filed on Aug. 27, 2002.
Application No. 10/921,387 is a continuation-in-part of application No. 10/229,954, filed on Aug. 27, 2002, now Pat. No. 6,791,130.
Application No. 10/921,387 is a continuation-in-part of application No. 10/229,955, filed on Aug. 27, 2002.
Application No. 10/921,387 is a continuation-in-part of application No. 10/229,956, filed on Aug. 27, 2002, now Pat. No. 6,798,033.
Application No. 10/921,387 is a continuation-in-part of application No. 10/648,129, filed on Aug. 26, 2003, now Pat. No. 6,809,358.
Application No. 10/921,387 is a continuation-in-part of application No. 10/746,529, filed on Dec. 23, 2003.

(51) Int. Cl. H04N 3/14; H04N 5/335

(52) U.S. Cl. 348/317

(57) ABSTRACT

An electronic imaging sensor. The sensor includes an array of photo-sensing pixel elements for producing image frames. Each pixel element defines a photo-sensing region and includes a charge collecting element for collecting electrical charges produced in the photo-sensing region, and a charge storage element for the storage of the collected charges. The sensor also includes charge sensing elements for sensing the collected charges, and charge-to-signal conversion elements. The sensor also includes timing elements for controlling the pixel circuits to produce image frames at a predetermined normal frame rate based on a master clock signal (such as 12 MHz or 10 MHz). This predetermined normal frame rate which may be a video rate (such as about 30 frames per second or 25 frames per second) establishes a normal maximum per frame exposure time. The sensor includes circuits (based on prior art techniques) for adjusting the per frame exposure time (normally based on ambient light levels) and novel frame rate adjusting features for reducing the frame rate below the predetermined normal frame rate, without changing the master clock signal, to permit per frame exposure times above the normal maximum exposure time. This permits good exposures even in very low light levels. (There is an obvious compromise of lowering of the frame rate in conditions of very low light levels, but in most cases this is preferable to inadequate exposure.) These adjustments can be automatic or manual.

### CROSS REFERENCE TO RELATED APPLICATIONS

This application is a continuation in part of U.S. patent application Ser. No. 10/921,387, filed Aug. 18, 2004 which was a continuation in part of Ser. No. 10/229,953 filed Aug. 27, 2002; Ser. No. 10/229,954 filed Aug. 27, 2002, now U.S. Pat. No. 6,791,130; Ser. No. 10/229,955 filed Aug. 27, 2002; Ser. No. 10/229,956 filed Aug. 27, 2002, now U.S. Pat. No. 6,798,033; Ser. No. 10/648,129 filed Aug. 26, 2003, now U.S. Pat. No. 6,809,358; and Ser. No. 10/746,529 filed Dec. 23, 2003, all incorporated herein by reference. Ser. No. 10/648,129 was a continuation in part of Ser. No. 10/672,637 filed Feb. 5, 2002 now U.S. Pat. No. 6,370,914 which is also incorporated herein by reference.

### FIELD OF THE INVENTION

The present invention relates to cameras and camera components and in particular CMOS image sensors and to cameras with CMOS image sensors.

### BACKGROUND OF THE INVENTION

Electronic cameras comprise imaging components to produce an optical image of a scene onto a pixel array of an electronic image sensor. The electronic image sensor converts the optical image into a set of electronic signals. These electronic cameras often include components for conditioning and processing the electronic signals to convert them into a digital format so that the images can be processed by a digital processor and/or transmitted digitally. Electronic image sensors are typically comprised of arrays of a large number of very small light pixel detectors, together called “pixel arrays”. These sensors typically generate electronic signals that have amplitudes that are proportional to the intensity of the light received by each of the pixel detectors in the array. Various types of semiconductor devices can be used for acquiring the image. These include charge couple devices (CCDs), photodiode arrays and charge injection devices. The most popular electronic image sensors utilize arrays of CCD detectors for converting light into electrical signals. These detectors have been available for many years and the CCD technology is mature and well developed. One big drawback with CCD's is that the technique for producing CCD's is incompatible with other integrated circuit technology, so that processing circuits and the CCD arrays must be produced on separate chips.

Another currently available type of image sensors is based on metal oxide semiconductor technology or complementary metal oxide semi-conductor technology. These sensors are commonly referred to as MOS or CMOS sensors. The most common CMOS sensors have photo-sensing circuitry and active processing circuitry designed in each pixel cell. They are called active pixel sensors. The active circuitry consists of multiple transistors that are inter-connected by metal lines; as a result, this region of the sensor with the transistors and metal lines is typically opaque to visible light and cannot be used for photo-sensing. Thus, each pixel cell typically comprises a photosensitive region and a non-photosensitive region. In addition to circuitry associated with each pixel cell, CMOS sensors have other digital and analog signal processing circuitry, such as sample-and-hold amplifiers, analog-to-digital converters and digital signal processing logic circuitry, all integrated as a monolithic device. Both pixel arrays and other digital and analog circuitry may be fabricated using the same basic process sequence on the same substrate. Small visible light cameras using CMOS sensors on the same chip with processing circuits have been proposed. (See for example U.S. Pat. No. 6,486,503.)

Small cameras using CCD sensors consume relatively large amounts of energy and require high rail-to-rail voltage swings to operate the CCD sensor. This can pose problems for today's mobile appliances, such as Cellular Phone and Personal Digital Assistant. On the other hand, small cameras using CMOS sensors may provide a solution for energy consumption; but the traditional CMOS-based small cameras suffer low light sensing performance, which is intrinsic to the nature of CMOS active pixel sensors caused by shallow junction depth in the silicon substrate and its active transistor circuitry taking away the real estate preciously needed for photo-sensing.

U.S. Pat. Nos. 5,528,043 5,886,353, 5998,794 and 6,163,030 are examples of prior art patents utilizing CMOS circuits for imaging. These patents have been licensed to Applicants' employer. U.S. Pat. No. 5,528,043 describes an X-ray detector utilizing a CMOS sensor array with readout circuits on a single chip. In that example image processing is handled by a separate processor (see FIG. 4 which is FIG. 1 in the '353 patent). U.S. Pat. No. 5,886,353 describes a generic pixel architecture using a hydrogenated amorphous silicon layer structure, either p-i-n or p-n or other derivatives, in conjunction with CMOS circuits to for the pixel arrays. U.S. Pat. Nos. 5,998,794 and 6,163,030 describe various ways of making electrical contact to the underlying CMOS circuits in a pixel. All of the above U.S. patents are incorporated herein by reference.

A need exists for an improved electronic image sensor which can provide cameras with cost, quality and size improvements over prior art cameras.

### SUMMARY OF THE INVENTION

The present invention provides an electronic imaging sensor. The sensor includes an array of photo-sensing pixel elements for producing image frames. Each pixel element defines a photo-sensing region and includes a charge collecting element for collecting electrical charges produced in the photo-sensing region, and a charge storage element for the storage of the collected charges. The sensor also includes charge sensing elements for sensing the collected charges, and charge-to-signal conversion elements. The sensor also includes timing elements for controlling the pixel circuits to produce image frames at a predetermined normal frame rate based on a master clock signal (such as 12 MHz or 10 MHz). This predetermined normal frame rate which may be a video rate (such as about 30 frames per second or 25 frames per second) establishes a normal maximum per frame exposure time. The sensor includes circuits (based on prior art techniques) for adjusting the per frame exposure time (normally based on ambient light levels) and novel frame rate adjusting features for reducing the frame rate below the predetermined normal frame rate, without changing the master clock signal, to permit per frame exposure times above the normal maximum exposure time. This permits good exposures even in very low light levels. (There is an obvious compromise of lowering of the frame rate in conditions of very low light levels, but in most cases this is preferable to inadequate exposure.) These adjustments can be automatic or manual.

### Preferred Embodiment

In a preferred embodiment the predetermined normal video frame rate is determined by a master clock frequency signal (at for example 12 MHz) divided by the product of two numbers representing: (1) the maximum number of rows of pixels, row-max and (2) the maximum number of columns of pixels, col-max. Default values of these two numbers are preferably factory set (for example, at 508 for row-max and 782 for col-max) by the sensor fabricator providing a frame rate of 30.2 Hz. With this frame rate the predetermined normal maximum per frame exposure time is about 33 milliseconds. However, in this embodiment, provisions are made for a calculation of new row max values that are used instead of the factory set value of row-max whenever necessary to reduce the frame rate to achieve desired exposures in low light levels.

In this preferred embodiment charges generated in the pixels of each row of pixels are collected for a controlled period of time within the range of 65.2 microseconds to about 4.3 seconds. This charge collection time period is determined and set by a processor in the camera in which the sensor is utilized, within the above range, so as to achieve proper exposure (i.e. a desired quantity of charge collection in the pixels). Applicants refer to this charge collection time period as “shutter time” since it is equivalent to the time the shutter of a conventional (film type) camera is open. If the shutter time is less than the maximum per frame exposure time (about 33 milliseconds in this case) as it normally is, the frame rate will be determined using the factory set default value of row max (i.e. producing a frame rate of 30.2 fps with exposure times between 65.2 microseconds and about 33 milliseconds). If the shutter time is greater than the normal maximum per frame exposure time, a new calculated value of row-max is used to determine the frame rate so that the per frame exposure time is equal to the desired shutter time. With this technique the camera typically operates at the video rate of 30.2 Hz (with the camera controlling charge collection time periods to limit exposure) and at lower frame rates only when necessary to obtain desired exposures in low-light conditions. Thus, for video rate cameras using this sensor, desired exposures are automatically provided in low-light as well as good-light levels while avoiding prior art complications inherent in an adjustment of the master clock signal.

In preferred embodiments each pixel of the array includes light-sensing elements fabricated using CMOS techniques and CMOS or MOS based pixel circuits to store the charges and to convert the charges into electrical signals. In these preferred embodiments additional CMOS circuits in and/or on the same crystalline substrate are provided for parametric programming, chip timing, operation control and analog-to-digital data conversion circuits. A specific preferred embodiment is a CMOS sensor called the EPS 340C a 644×484 active pixel image array with 5 micron×5 micron pixels designed for operation at video frame rates up to about 30 frames per second when the input clock is at 12 MHz. The sensor has an integrated timing control that outputs a 10-bit digital video signal and synchronization clock signals. The sensor is designed as a versatile imaging sensor suitable for installation in a wide variety of electronic devices. Special features of the sensor permit sensor performance to be precisely controlled by software and electronics in the device in which the sensor is to be installed. The sensor is equipped with features permitting adjustable exposure time, and signal gain to accommodate various lighting conditions and sources. Specifically, sensor facilities permit camera controls to automatically reduced frame rates to permit adequate exposures times if light levels detected by the camera are below predetermined values. In an example embodiment where the nominal video rate is about 25 frames per second with an input clock at 10 MHz, the sensor is programmed to automatically reduce frame rates as necessary to maintain adequate exposure. The EPS304C achieves excellent image quality. The sensor has low light sensing capability, high pixel dynamic range and uses a special scheme for column fixed pattern noise reduction. The EPS304C maintains a consistent optical black level with its automated offset compensation circuitry so that variation in sensor output from sensor to sensor is minimal. Therefore, the sensor is useful as a component part of low-cost mass-produced electronic consumer products such as cell phones and digital cameras. The EPS304C can operate from a single 3.3V DC bias voltage or with 3.3V and 2.5V dual supplies.

### BRIEF DESCRIPTION OF THE DRAWINGS

FIGS. 1A and 1B are drawings of cellular phones equipped with a camera utilizing a CMOS sensor array according to the present invention.

FIG. 1C shows some details of the camera.

FIG. 2 shows some details of a CMOS integrated circuit utilizing some of the principals of the present invention.

FIG. 3A is a partial cross-sectional diagram illustrating pixel cell architecture for five pixels of a sensor array utilizing principles of the present invention.

FIG. 3B shows CMOS pixel circuitry for a single pixel.

FIG. 3C shows a color filter grid pattern.

FIGS. 4A, 4B and 4C show features of a CMOS imaging sensor.

FIG. 5 shows a pixel array layout

FIG. 6 shows relations between pixel circuits and amplifiers and analog to digital converters.

FIGS. 7 and 8 shows how image data may be handled.

FIG. 9 shows a CMOS sensor with a “N-I-P” surface layer with the N layer under the surface electrode layer.

FIG. 10A shows a CMOS sensor with a “P-I-N” surface layer with the P layer under the surface electrode layer.

FIGS. 10B-10E show additional features of the FIG. 10A sensor.

### DETAILED DESCRIPTION OF A PREFERRED EMBODIMENT

In the following description of preferred embodiments, reference is made to the accompanying drawings, which form a part hereof, and which show by way of illustration specific embodiments of the invention. It is to be understood by those of working skill in this technological field that other embodiments may be utilized, and structural, electrical, as well as procedural changes may be made without departing from the scope of the present invention.

### Tiny 300,000-Pixel Camera

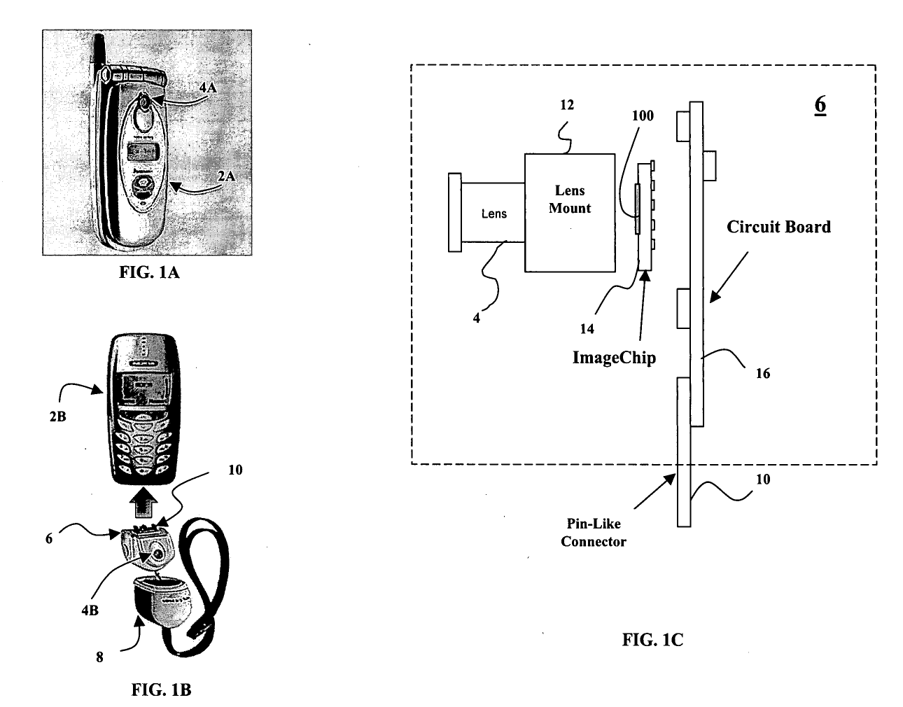

A preferred embodiment of the present invention is a single chip camera with a sensor consisting of a photodiode array comprising of photoconductive layers on top of an active array of CMOS circuits. (Applicants refer to this sensor as a “POAP Sensor” the “POAP” referring to “Photodiode on Active Pixel”.) In this sensor there are 311,696 pixels arranged in as a 644×484 pixel array and there is a transparent electrode on top of the photoconductive layers. The pixels are 5 microns×5 microns and the packing fraction is approximately 100 percent. The active dimensions of the sensor are about 3.2 mm×2.4 mm and a preferred lens unit is a lens with a 1/4.5 inch optical format. The sensor also works well with a lens system based on the standard ¼ inch optical format. A preferred application of the camera is as a component of a cellular phone as shown in FIGS. 1A and 1B. In the 1A drawing the camera is an integral part of the phone 2A and the lens is shown at 4A. In the 1B drawing the camera 6 is separated from the phone 2B and connected to it through the 3 pin-like connectors 10. The lens of the camera is shown at 4B and a camera protective cover is shown at 8. FIG. 1C is a block diagram showing the major features of the camera 4B shown in FIG. 1B drawing. They are lens 4, lens mount 12, image chip 14, sensor pixel array 100, circuit board 16, and pin-like connector 10.

### CMOS Sensor

The sensor section is implemented with a photoconductor on active pixel array, readout circuitry, readout timing/control circuitry, sensor timing/control circuitry and analog-to-digital conversion circuitry. The sensor includes:
1) a CMOS-based pixel array comprised 644×484 CMOS pixel circuits covered with a photoconductive layer comprised of three sub-layers and a surface electrode layer and
2) CMOS readout circuitry.

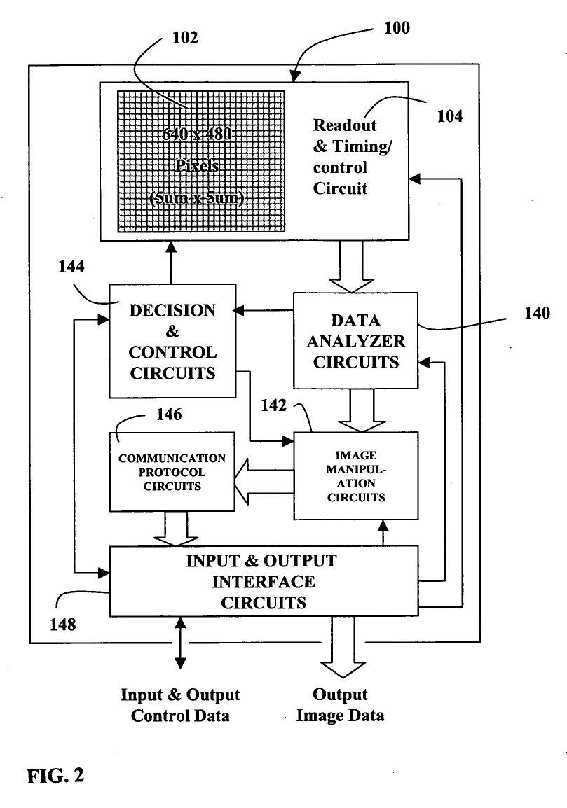

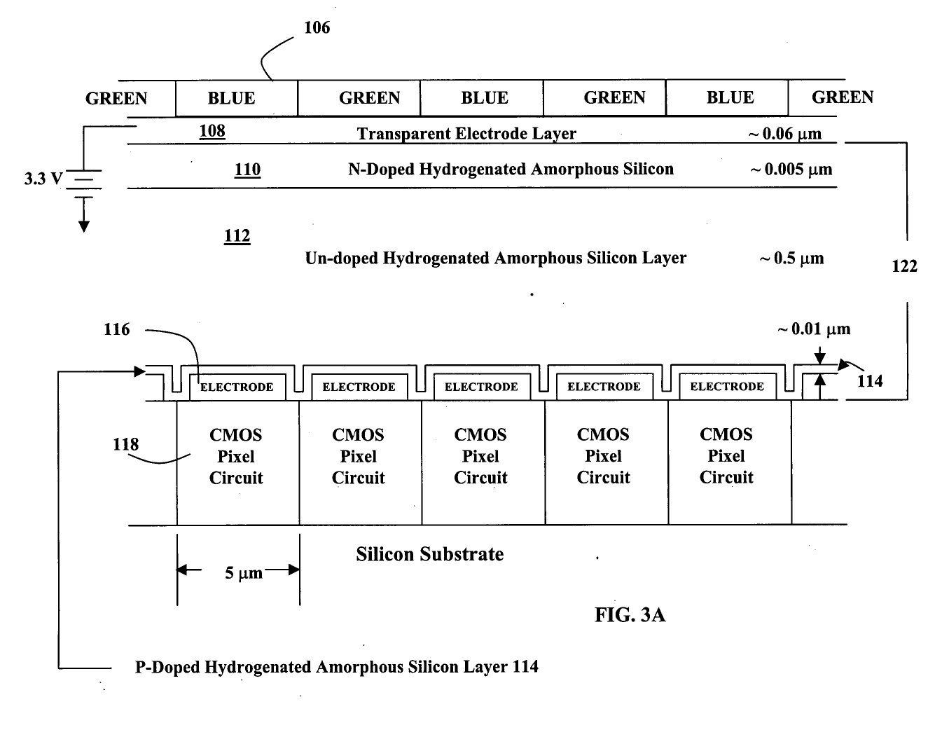

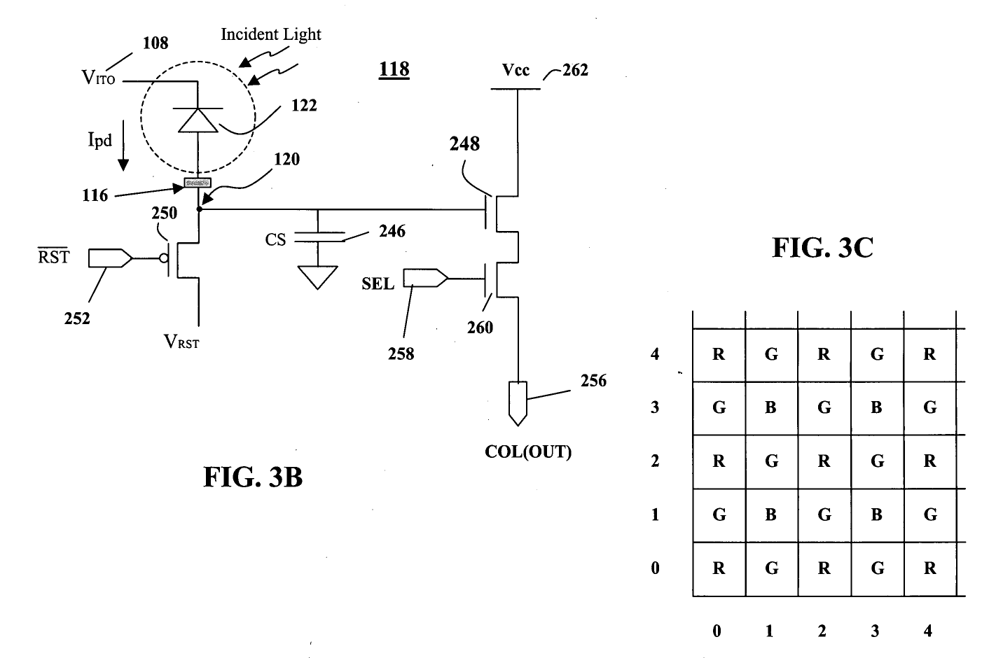

The sensor array is similar to the visible light sensor array described in U.S. Pat. No. 5,886,353 (see especially text at columns 19 through 21 and FIG. 27 of the '353 patent) that is incorporated by reference herein. Details of various sensor arrays are also described in the parent patent applications referred to in the first sentence of this specification all of which have also been incorporated herein by reference. FIGS. 2, 3A, 3B and 3C describe features of preferred sensor arrays for this cell phone camera. The general layout of the sensor is shown at 100 in FIG. 2. The sensor includes the pixel array 102 and readout and timing/control circuitry 104. These circuits are described in more detail in subsequent sections of this specification. FIG. 3A is a drawing showing the layered structure of a 5-pixel section of the pixel array.

The sensor array is coated with color filters and each pixel is coated with only one color filter to define only one component of the color spectrum. The preferred color filter set is comprises three broadband color filters with peak transmission at 450 nm (B), 550 nm (G) and 630 nm (R). The full width of half maximum of the color filters is about 50 nm for Blue and Green filters. The Red filter typically has transmission all the way into near infrared. For visible image application, an infrared cut-off filter needs to be used to tailor the red response to be peaked at 630 nm with about 50 nm full width of half maximum. These filters are used for visible light sensing applications. Four pixels are formed as a quadruplet, as shown in FIG. 3C. Two of the four pixels are coated with color filter of peak transmission at 550 nm, they are referred as “Green pixels”. One pixel is coated with color filter with peak at 450 nm (Blue pixel) and one with filter peaked at 630 nm (Red pixel). The two Green pixels are placed at the upper-right and lower-left quadrants. A Red pixel is placed at the upper-left quadrant and a Blue pixel is placed at lower-right quadrant. The color-filter-coated quadruplets are repeated for the entire 644×484 array. The edge-pixels surrounding the 640×480 array are covered with color filters as well to provide the boundary condition that allows imaging processor to generate good images with 640×480 pixels.

FIG. 3A shows a top filter layer 106 in which the green and blue filters alternate across a row of pixels. Beneath the filter layer is a transparent surface electrode layer 108 comprised of about 0.06 micron thick layer of indium tin oxide (sometimes referred to as an ITO layer or a TEL layer) which is electrically conductive and transmissive to visible light. Below the conductive surface electrode layer is a photoconductive layer comprised of three sub-layers. The uppermost sub-layer is an about 0.005 micron thick layer 110 of n-doped hydrogenated amorphous silicon. Under that layer is an about 0.5 micron layer 112 of un-doped hydrogenated-amorphous silicon. Applicants refer to this 112 layer as an “intrinsic” layer. This intrinsic layer is the one that displays high electrical resistivity unless it is illuminated by photons. Under the un-doped layer is an about 0.01 micron layer 114 of high-resistivity P-doped hydrogenated-amorphous silicon. These three hydrogenated amorphous silicon layers produce a diode effect above each pixel circuit. Applicants refer to the layers as a N-I-P photoconductive layer.

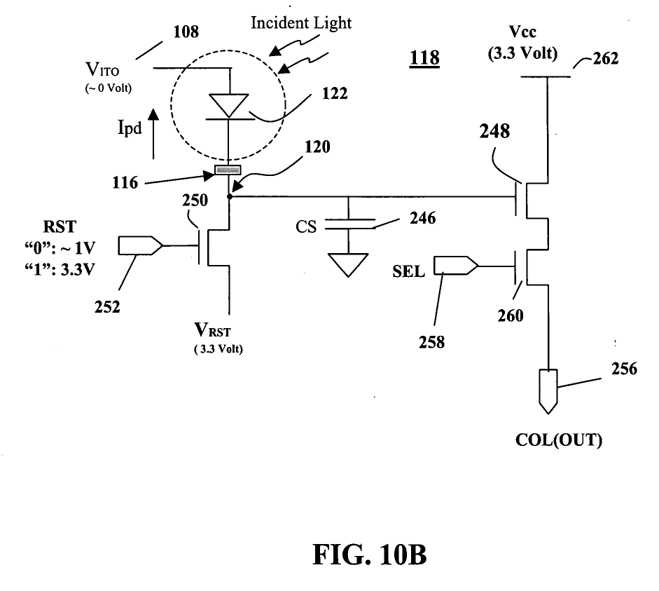

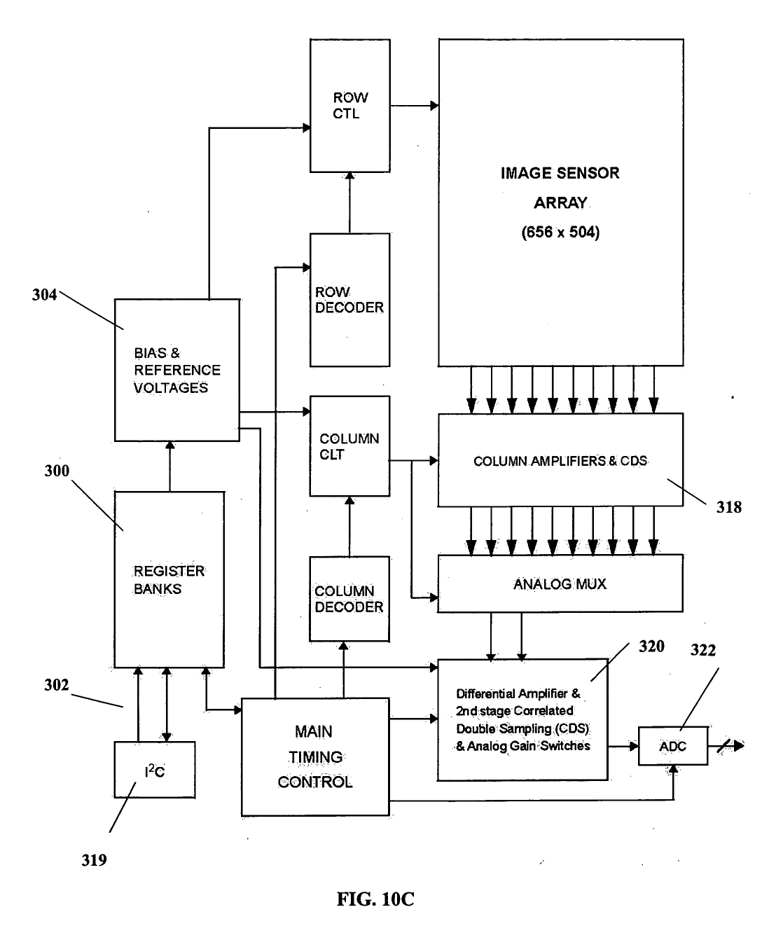

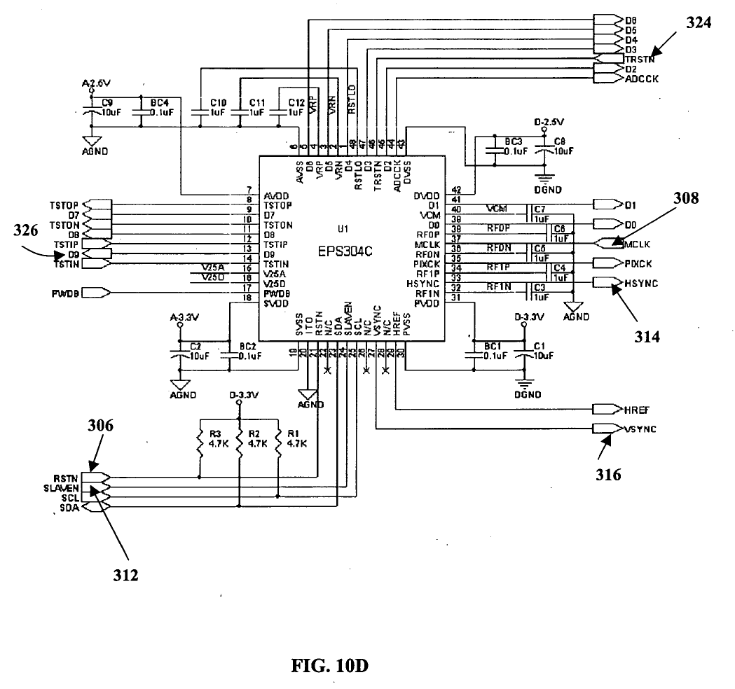

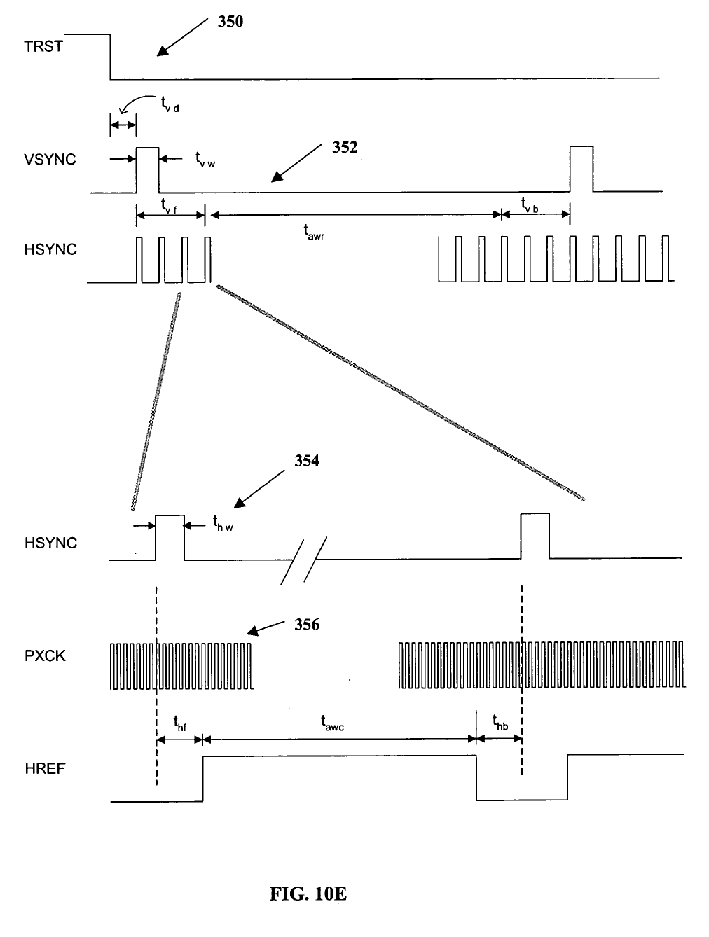

Carbon atoms or molecules are preferably added to bottom P-doped layer 114 to increase electrical resistance. This minimizes the lateral crosstalk among pixels and avoids loss of spatial resolution. It also avoids any adverse electrical effects at the edge of the pixel array where the transparent electrical layer 108 makes contact with the bottom layer 114 as shown in FIG. 10A at 125. This N-I-P photoconductive layer is not lithographically patterned, but (in the horizontal plane) is a homogeneous film structure. This simplifies the manufacturing process. Within the sub-layer 114 are 311,696 4.6 micron×4.6 micron electrodes 116 which define the 311,696 pixels in this preferred sensor array. Electrodes 116 are made of titanium nitride (TiN). Just below the electrodes 116 are CMOS pixel circuits 118 as shown in FIG. 3A. The components of pixel circuits 118 are described by reference to FIG. 3B. The CMOS pixel circuits 118 utilize three transistors 250, 248 and 260. The operation of a similar three transistors pixel circuit is described in detail in US Patent 5,886,353. This circuit is used in this embodiment to achieve maximum saving in chip area. Other more elaborate readout circuits are described in the parent patent applications referred to in the first sentence of this specification. Pixel electrode 116, shown in FIGS. 3A and 3B, is connected to the charge-collecting node 120 as shown in FIG. 3B. Pixel circuit 118 includes charge collection node 120, collection capacitor 246, source follower buffer 248, selection transistor 260, and reset transistor 250. Reset transistor 250 is a p-channel transistor and source follower transistor 248 and selection transistor 260 are n-channel transistors. The voltage at COL (out) 256 is proportional to the charge Q(in) stored on the collection capacitor 246. By reading this node twice, once after the exposure to light and once after the reset, the voltage difference is a direct proportional to the amount of light being detected by the photo-sensing structure 122. Pixel circuit 118 is referenced to a positive voltage Vcc at node 262 (typically 2.5 to 5 Volts). Pixel circuitry for this array is described in detail in the '353 patent. One of the alterative embodiments is to use P-I-N diode where P-layer is directly under the transparent electrode and N-layer makes an electrical contact with the TiN pixel electrode. In this alternate embodiment, an n-channel transistor is used for the reset transistor.

### Model EPS304C Imaging Sensor

Applicants have described below special features of a specific preferred embodiment of the present invention. This sensor, Model EPS304C imaging sensor, is expected to be produced in great numbers and is expected to sell for less than a few U.S. dollars each. The sensor is expected to be incorporated into a wide variety of electronic devices.

General Description

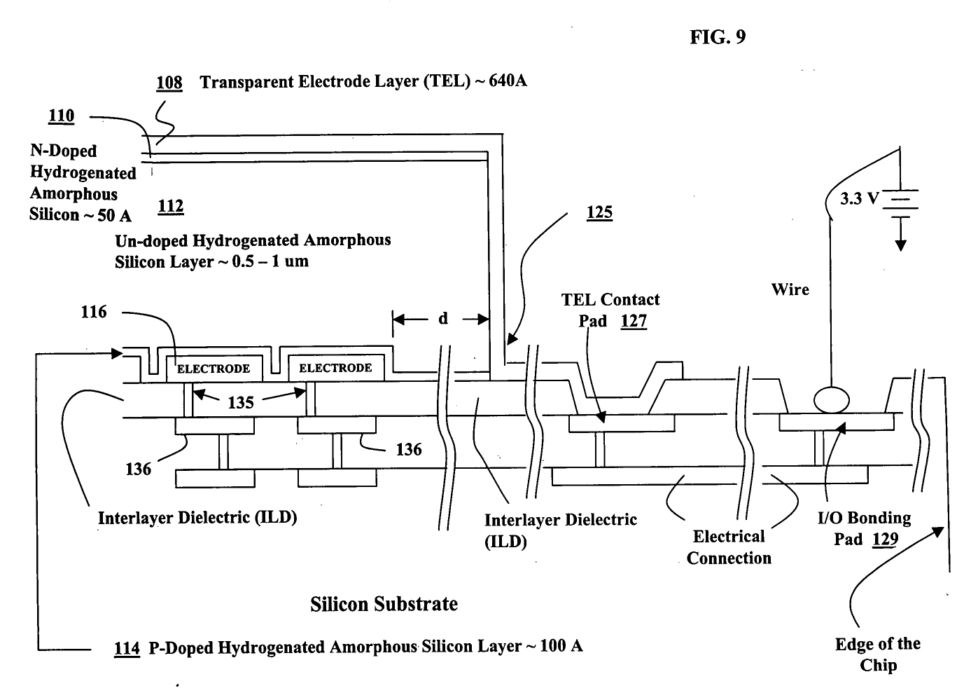

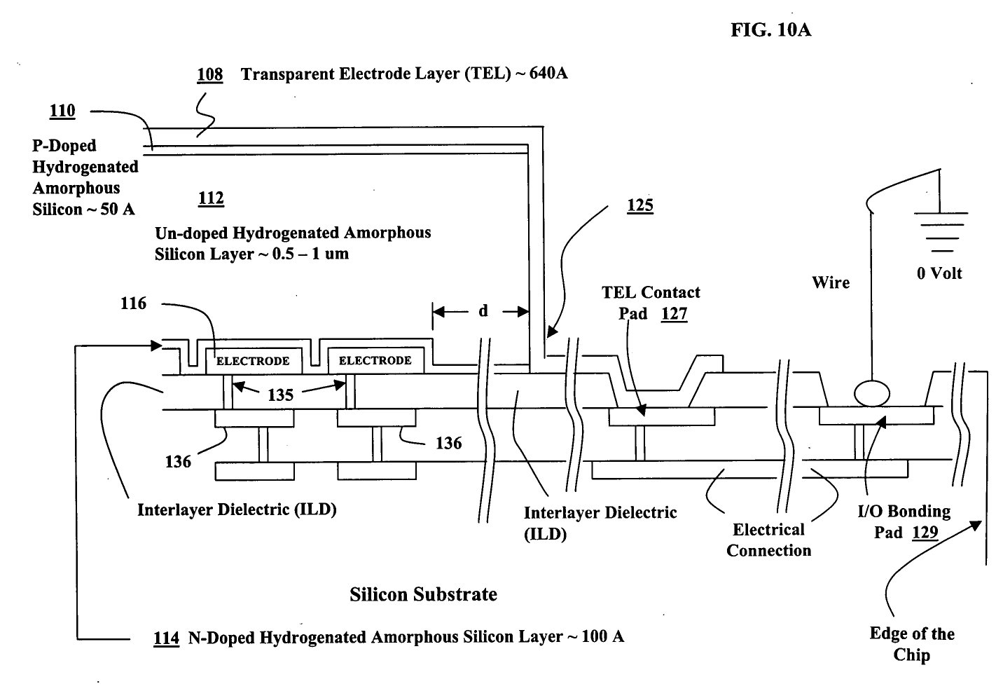

The Model EPS304C sensor provides a 644×484 active pixel image array with 5 μm×5 μm pixels designed of operation at video frame rates up to 30 frames per second. The sensor has an integrated timing control that outputs a 10-bit digital video signal and synchronization clock signals. The sensor is designed as a versatile imaging sensor suitable for installation in a wide variety of electronic devices. Special features of the sensor permit sensor performance to be precisely controlled by software and electronics in the device in which the sensor is to be installed. Features of the sensor are specifically described in FIGS. 10A, 10B, 10C, 10D, and 10E. The sensor is equipped with features permitting adjustable exposure time, and signal gain to accommodate various lighting conditions and sources. Specifically, sensor facilities permit camera controls to automatically reduced frame rates from fewer than the nominal video rate of 30 frames per second to permit adequate exposures times if light levels detected by the camera are below predetermined values. The EPS304C sensor achieves excellent image quality. The sensor has low light sensing capability, high pixel dynamic range and uses a special scheme for column fixed pattern noise reduction. The EPS304C maintains a consistent optical black level with its automated offset compensation circuitry so that variation in sensor output from sensor to sensor is minimal. Therefore, the sensor is useful as a component part of low-cost mass-produced electronic consumer products such as cell phones and digital cameras. The EPS304C can operate from a single 3.3V DC bias voltage or with 3.3V and 2.5V dual supplies. It is controlled and can be reconfigured via a standard serial interface. The pixel circuitry and photodiode layer arrangement in the EPS304C is substantially as described in FIGS. 9, 10A-E; however, in the case of this embodiment the p-layer is at the top (adjacent to TEL layer 108) and the n-layer is at the bottom (adjacent to the pixel electrodes 116) as shown in FIG. 10A. The Applicants refer it as a P-I-N photodiode. The pixel reset operation places a charge on each pixel electrode capacitor 246 as shown in FIG. 10B that is partially drained during to surface electrode 108 (at ground potential [zero volts] as indicated in FIGS. 10A and 10B) during exposure periods to provide a pixel exposure value for the pixel. This sensor provides row-based rolling access to each pixel electrode capacitor 246 at frame rates up to 30 fps with readout circuitry as described above in the section entitled “CMOS Sensor” with reference to detailed circuit descriptions on U.S. Pat. No. 6,809,358 that has been incorporated herein by reference. EPS304C also allows camera designer to output the video of a sub-window within the full 644×484 pixel array. Since the region of interest is smaller, one can then reduce the scanning space. As a result of the reduction of scanning space, frame rates higher than 30 frames per second can be achieved for a given input master clock.

Programmable Registers

The EPS304C sensor comprises register bank 300 (FIG. 10C) of 68 relevant programmable registers that can be programmed to fit particular needs of the electronic device in which the sensor is to be utilized. The registers can be permanently set during the fabrication of the device or the device can be programmed and equipped with facilities to permit the registers to be set and/or reset by the user. Register settings can also be changed real time by control processors in the electronic devices in which the sensor is incorporated. This feature makes this sensor extremely versatile and useful if a wide variety of devices. Due to the communication protocol used by the serial interface (I2C), these registers have bit width of 8-bit or less and a range of 0 to 255. For parameters need to be larger than 255, the inventors use multiple 8-bit registers to store the values. Some of the registers are described below to illustrate the flexibility of EPS304C to accommodate various applications.
1. One video mode selection register is programmed at the factory to provide a default video stream of 644×484; however, this register allows camera to switch to a custom-defined video mode that can provide a video stream of size different from the default.
2. Two shutter time registers are combined to make a 16-bit number as the Shutter Time in unit of line time. They are used to control how long the charges generated in photodiode either under light or in the dark would be integrated. The Shutter Time needs to be larger than 0 and has a range from 1 to 65535 line times. (A line time in a preferred embodiment is 65.2 microseconds.)
3. Four sensor control registers enable or disable a function of EPS304C or toggle between two operation modes.
4. One pixel reset low voltage control register defines the analog voltage 252 applied to the gate of the reset transistor 250 in FIG 10B when this transistor is considered LOW (a digital “0” state). It is to prevent the transistor 250 become conductive in “0” state. In contrast, when 252 is HIGH (a digital “1” state), the analog voltage applied to the gate of this reset transistor 250 goes to Vcc (3.3V in EPS304C). During a pixel reset, a digital “HIGH” state at 252, the voltage at the charge collection node 120 is reset to about 2.6V (i.e. Vcc=3.3V less a transistor threshold voltage of about 0.7V). After the pixel is reset, 252 would go back to the LOW state (a digital “0” state) with an analog voltage about 1V. This still makes the reset transistor 250 “off” and the charge collection node 120 electrically floating. During the pixel integration time, the charge collection node collects charges (optically or thermally generated) and its voltage drops below 2.6V. Because 252 is held at about 1V during the pixel integration time, 120 would not go below 1V. This determines more or less the voltage swing of the pixel voltage of about 1.6V (from 2.6V to 1V). The inventors make this voltage programmable in order to fine-tune the sensor performance in signal dynamic range. Under a nominal operation, this register does not need to be changed.
5. Four registers to define the size of the scanning window, two for the height and two for the width.
6. Four registers to define the size of an active window, two for the height and two for the width. The active window size cannot exceed the size of the scanning window.
7. Eight registers to define the sub-window within the active window; four for the vertical direction and four for the horizontal direction.
8. Two registers set the width of the synchronization signals, one for the vertical sync and the other one for the horizontal sync.
9. Four registers allow the camera processor to change the gain for each of the color, G1, R, B, G2 in FIG. 3C. This flexibility is to support white balance under various light sources. The range of the gain is from 0.5 to 2.
10. Two registers control the internal reference voltage used in the analog signal chain. These are primarily reserved for the inventors to do circuit design validation by moving the baseline voltage up and down relative to the input range of ADC. They are not supposed to be changed by the camera in the field. However, a by-product of this design is to allow camera processor to clamp the baseline voltage of the dark reference at a lower voltage than the reference voltage of the ADC for the digital number “0”. As a result of it, it would suppress the noise in the dark. In some imaging applications, this artificial dark noise suppression may be desirable.
11. Two registers set the digital offset of the ADC output. This can be used to clamp the output of ADC at a selected level. This is a good feature mainly useful during the initial sensor design validation phase and during production testing.
12. Two registers define the convergence range for the dark reference level used by the on-chip automatic dark compensation circuit; one for the upper bound and one for the lower bound.
13. One read-only register shows the final dark reference level converged by the on-chip dark compensation circuit.
14. Two registers allow the user to change the latency of the output of active window relative to the sync signal; one for row and one for column.
15. One register sets the global gain to the signal, which includes a combination of change of gains in analog and digital circuits.
16. Two registers set the global offset to the signal. This is done in the digital domain and can be a positive or negative number.

There are other registers are mainly used for sensor design validation and not used in the field. In summary, EPS304C has three kinds of registers: (1) registers to be used in the field, (2) registers to be used during the design validation and (3) registers to be used during production testing.

Video Timing Components

The Model EPS304C sensor comprises special features for video timing control. Two internal counters are used to control the sensor scanning, a row counter and a column counter. The row counter counts from 0 to a factory or user selected row maximum number and the column counter counts from 0 to a factory or user selected column maximum number. These selected maximum numbers define a scanning space. These numbers also define the pixel line rates and the frame rates of a selected scanning mode for a given master clock. The sensor needs only one master clock. The pixel rate follows the master clock rate. Another important rate is the line rate. The line rate is the pixel rate divided by the column maximum number. The frame rate is the line rate divided by the row maximum number. The line time is the inverse of the line rate. In a preferred arrangement that Applicants refer to “Mode 0”, a row maximum number of 508 and a column maximum number of 782 are selected. If the input master clock is 10 MHz, a line rate of 12.79 KHz (10 MHz/782) and the frame rate of 25.2 Hz (12.79 KHz/508) are derived. (Increasing the master clock rate to 12 MHz provides a frame rate of about 30.2 Hz.) In this preferred mode (see below) the line time is 78.2 microseconds.

Important timing parameters, with the “0 Mode” scanning (for example, at 25.2 fps when the master clock is at 10 MHz), are given in the table below:

| | |
|---|---|
| Master clock frequency | 10 MHz |
| Master clock period | 100 ns |
| Pixel clock period (T_{c}) | 100 ns |
| Line time (Tₗ) | 782 × 100 = 78200 ns |
| Frame time (T_{f}) | 508 × 78299 = 0.0397 s |
| Height of active window | 504 lines |
| Width of active window | 656 pixels |
| Frame Rate | 25.2 fps |

EPS304C's circuit is designed to functional properly with master clock maximum to 13.5 MHz and with the clock at 12 MHz the frame rate is 30 fps. EPS304C is designed to have its pixel clock follow the master clock. For example, when the master clock is 10 MHz, pixel clock is 10 MHz. If the master clock is 12 MHz, then the pixel clock becomes 12 MHz. The line time and the frame time are actually derived from the pixel clock period (the smallest timing unit). FIG. 10E shows some of the timing characteristics of the sensor in the scanning Mode 0; this figure is used for illustration purpose but not in real scale. A reset signal is displayed at 350 and the first vertical synchronization signal 352 with its leading edge at about 40 line time later, (due to some of the setup time for the signal to go through the entire signal chain), horizontal synchronization signals where the first horizontal sync signal has the leading edge lined up with the leading edge of the first vertical sync signal, and a pixel clock signal 356. The symbol “t_{HW}” (“HW” refers to “horizontal width”) shows the width of the horizontal sync signal in units of Tc (clock period). The symbol “t_{HF}” (“HF” refers to “horizontal front” blank time) describes the time delay in units of Tc from the beginning of a row (defined by the leading edge of the horizontal sync signal) to the horizontal edge of the active window. This timing relationship is maintained for every row. The symbol “t_{AWC}” (“AWC” refers to “active window columns”) and is a measure of the width of the active window, in units of Tc. The symbol “t_{HB}” (“HB” refers to “horizontal back” blank time) represents the time elapse from the last pixel in an active row to the beginning of next active row. From FIG. 10E at 357, one can easily realize that one line time (T₁)=“t_{HF}”+“t_{AWC}”+“t_{HB}”.

### Model EPS304C Functional Description

Fully Integrated Timing Circuit

The EPS304C image sensor is designed with a fully integrated timing circuit. There are 68 relevant registers in register bank 300 shown in FIG. 10C that can be read and programmed through a 2-wire series interface 302 which is compatible with I²C buses. (The I²C bus, developed by Philips Semiconductors in the 1980's, is a well-known, simple bi-directional 2-wire bus for efficient integrated circuit control. The bus is also called the “Inter-IC bus”.) Other registers, in addition to the above 68 registers are provided for design validation and are used by the designers only. The EPS304C sensor can operate from a single 3.3V DC supply and master clock input. It provides its own bias and reference voltages as indicated at 304 in FIG. 10C. It can also be operated with a 3.3V and 2.5V dual supply mode. At power on, the EPS304C sets all registers to default values. It also automatically initiates a timing reset and a continuous video stream begins thereafter. At any time a sensor reset can be forced by toggling the reset (RSTN) pin as indicated at 306 in FIG. 10D. This makes the EPS304C return to its default state. EPS304C operates by default as a timing master. However, it also accepts an external master clock as indicated at 308 and it can generate a video timing signal internally. The EPS304C can also accept external synchronization signals as a timing reference. This “SLAVE” mode can be set using a slave pin (SLAVEN) as indicated at 312. This mode is reserved for non-traditional applications that need precise timing control by the central controller of an electronic device such as a camera. When this mode is selected, an external “Pixel Clock” should be connected to the master clock (MCLK) pin 308, an external horizontal synchronization pulse should be connected to the sensor's HSYNC pin 314 and an external frame synchronization pulse should be connected to the sensor's VSYNC pin 316. The EPS304C's timing registers are described in Items 5-7 in the list of registers in the above section entitled “Programmable Registers”. These registers should be programmed to synchronize the EPS304C's video stream with the external timing of the camera. The EPS304C requires a minimum of 20 master clock cycles as the width of its horizontal synchronization pulse.

Row-Based Rolling Reset Technique

The EPS304C image sensor uses a row-based rolling reset technique. The lower left corner of a selected window is defined as (0, 0). The line number increases from bottom to top and column number increases from left to right. The EPS304C uses a Bayer Color Filter array arranged with an R-G1-G2-B configuration as indicated in FIG. 3C. All active pixels (644×484 of them) are covered with color filters. The (0, 0) pixel of the physical array is a RED pixel as indicated in FIG. 3C. When operation begins the bottom row of the selected window is reset. After reset the pixels in the selected row begin integration immediately. Under nominal operation, the integration time can be set between 1 and 504 (row maximum) line times. A line time consists of t_{HF} plus t_{AWC} plus t_{HB} which as explained above is the active window column readout time plus some blank time prior to and after the readout time. The actual line time depends upon the master input clock (MCLK), active window size, and other register parameters. Each row is reset after the signal of the row is transferred to the column buffer. This produces a reference signal that is used for double sampling (DS). In Applicants' preferred implementation each row can be reset while other rows are integrated. When a row has finished integration the signal is transferred to an analog buffer in the Column Amplifier and Column Double Sampling circuit 318 as shown in FIG. 10C. It is read twice, once for the pixel signal and another time for the reference signal. Both signals are transferred further to the next stage, a programmable gain amplifier 320 and an on-chip pipelined analog to digital converter 322. Amplifier 320 converts the signal-reference-pair into differential signals, and the Analog to Digital (A to D) converter 322 converts the differential analog input signals into a digital output. This readout scheme is used to remove the column-offset variations.

A to D Converter Calibration

The EPS304C uses a 10-bit pipelined A to D converter 322 with self-calibration. The calibration is automatically performed at chip power up and every time an OPMODE bit is toggled. This guarantees the A to D converter's linearity dynamically.

On-Chip Dark Compensation

The EPS 304C has an on-chip dark compensation circuit. Some of the edge pixels are covered with a light shield. The outputs of these pixels are utilized as a “black” reference. The average output of these pixels is automatically subtracted from the active pixels. Applicants call this circuit an “Automated Optical Black Compensation Circuit”. This can be done in analog or digital circuitry; however, the author's preferred embodiment is to do it using digital circuits. This feature is discussed in more detail in a following section entitled “Black Compensation”.

Sensor can be Master or Slave

The EPS304C can be a timing master or a slave at any given time. As a timing slave, the EPS304C accepts external synchronization clocks. As a timing master, the EPS304C provides clock signals PIXCK, HSYNC, VSYNC and HREF (as suggested in FIG. 10D) to facilitate ease of integration with other video capture devices. All digital outputs of the EPS304C use 3.3V CMOS logic for broader compatibility with other integrated circuits. EPS304C can be easily modified to use CMOS logic of other voltage, such as 2.8V or 2.5V. The pixel clock signal PIXCK has the same frequency as the master clock signal MCLK. Normally the EPS304C image sensor supplies continuous video stream after power up.

Timing Circuit

The TRSTN pin (referring to “timing reset pin”) 324 can be used to enable the start of a new frame. When the TRSTN pin is toggled, a “timing-reset” will be initiated. This feature can be used to trigger the EPS304C and to align its first valid VSYNC (referring to “valid synchronization”) signal to an external event. Under normal conditions, (TRSTN=HIGH), the EPS304C sends a continuous video stream until the power is removed or the power-saving mode is initiated. All synchronization signals such as PIXCK, HSYNC, VSYNC and HREF, can be referred back to the rising edge of TRSTN; and they are all aligned with the rising edge of PIXCK. See FIG. 10E for the graphical illustration of the video timing.

### Special Features

Special features of the EPS304C include:
Image array size: 656 (W)×504 (H)
Active array: 644 (W)×484 (H)
Pixel size: 5 μm×5 μm
Optical format: 1/4.5″ (pixel array diagonal: 4 mm)
Fill factor: close to 100% (no need for Micro-lens)
(Quantum Efficiency)×(Fill Factor) (@550 nm): >80%
Spectral response: 380 nm˜700 nm; no need for IR cut-off filter for white balance.
Mosaic RGB Bayer color filter array.
Video format: VGA progressive.
Signal type: 10 bits parallel raw video (RGRGRG . . . GBGBGB . . . ).
Frame rate: up to 30 VGA frames per second
Automated Optical Black compensation circuit.
On-chip circuitry for column fixed pattern noise reduction.
Output pixel, line, frame and active-pixel sync signals as timing master.
Programmable active window.
Accept pixel, line and frame sync signals input as a timing slave.
Programmable vertical and horizontal blank periods and widths.
Programmable exposure time and frame rate.
Programmable gain from 0 dB to 18 dB in 0.188 dB increment.
Programmable white-balance gain.
Non-disrupted video when change Gain settings.
Programmable registers via a two wire serial interface, I2C slave-mode compatible.
Can be triggered by external signal.
Power down mode.
Fully integrated timing with a single input master clock up to 12 MHz.
Single 3.3 volt power supply with tolerance range of 2.8V˜3.6V.
Dual power supply mode, 3.3V and 2.5V
48-pin or 32-pin SPLCC package.

### Details of Some Important Special Features

Black Compensation

As described above, one of the special features of the EPS304C is its “Automated Optical Black Compensation Circuit”. For camera applications, it is a necessary to establish a black reference in an image in order to generate good images. However, this dark reference may vary from chip to chip due to the variation of the manufacturing process. Conceptually, one can imagine solving this problem by calibrating the sensor individually at factory and storing calibrated parameters somehow so sensors can use them to produce a consistent signal level as the dark reference. However, if one thinks a bit deeper on the implementation, it becomes obvious that this approach is not practical. Let's say that one uses a non-volatile memory to store those parameters in a separate chip. This memory chip needs to mate with the specific image sensor at all time. This not only increases the cost but also create a logistic nightmare since one needs to track both chips in every step of the system assembly. Another possible solution is to try to solve this problem by storing those parameters on the same chip as the sensor. The reader should keep in mind that these parameters need to be stored in non-volatile memory so their values do not go away when the “power” is removed. In today's semiconductor manufacturing technology, it is not a trivial matter to integrate a process of making non-volatile memory to a process making other CMOS-based logic circuitry since these two processes are not totally compatible. Therefore, if one insists on storing the parameters on the same chip, one needs to use a process almost double the complexity and therefore the cost. Even though such process indeed exists in the market place, the cost is much higher than a typical CMOS and chips made with such process not widely available. And using such a process to make the product would create a logistic problem of how to program the parameters at the factory. The sensor would first need to be calibrated and then the parameters would have to be programmed into non-volatile memory. Most commercial test equipment in use today has only the capability of programming the chip with certain standard voltage levels: typically 5V, 3.3V, 2.5V or 1.8V. However, non-volatile memory typically needs more than 10V to program. Therefore, one would need to modify the test equipment to accommodate this requirement. This is doable, but it is costly. The EPS30C solves the problem with a built-in circuit to remove the chip-to-chip dark offset automatically and dynamically. This on-chip “dark compensation” circuit uses the dark pixels at the edges of the pixel array to establish a global dark reference. These dark pixels are just like the regular pixels except they are covered with light shield, for example a light shield made of metal. Signals from these pixels are subtracted (either digitally or electrically) from active pixel signals to provide the dark compensation.

Master or Slave

Another special feature described above is the ability to use the EPS304C as a timing master or a timing slave. This feature allows EPS304C to be integrated to other camera system ASIC with great flexibility. In today's market place, camera designs contemplate that the sensor will provide the master timing and the camera ASIC's operate as a timing slave. They expect sensors to provide the timing reference to synchronize the data stream. At the other end of the spectrum, some cameras operate as the timing master, where sensors need to follow the timing instruction from the camera ASIC's. EPS304 is designed to have both circuits on the same chip so EPS304 can work with both types of camera ASIC's, which is selectable by software. This design provides EPS30C the capability to work with all kinds of camera ASIC's without long and costly hardware changes.

Exposure Time Control

As explained above the sensor includes shutter timing register that permits shutter exposure times to be adjusted as needed to provide desired pixel exposures. An image frame time includes not only the time to stream out all the active pixels but also the circuit set up time (that may be referred to as blank lines or columns in unit of pixel clock cycle) needed for timing synchronization. Video image sensors are typically designed to run “video rate”, about 30 frames per second (fps), to capture real-time video streams. The frame time is just the inverse of the frame rate, about 1/30 seconds. In a typical design, frame time is determined first and the exposure time of the sensor cannot exceed the frame time (typically 1/30 second). The Applicants have implemented a different design strategy where EPS304C can be automatically programmed run at a frame rate lower than the nominal video rate of about 30 fps (corresponding to a frame time longer than 1/30 second) when necessary to provide desired pixel exposure. To be compatible with typical camera equipment, under normal condition, EPS304C follows the prior art practice of having the user define the frame time first and adjust the exposure time within the frame time allowed (i.e., between about 0 seconds and about 1/30 second). However, the sensor can be programmed so that during periods when the light level is not sufficient for adequate exposure, the user can designate an exposure time larger than that permitted by the default frame rate, and the frame rate will automatically be reduced to substantially less than 30 fps to permit the desired exposure time. To provide the user (camera design engineer) even greater ease-of-use, the Applicants have further implemented a design allowing the user to increase the exposure time beyond the maximum without worrying about changing the frame rate first. This is a very convenient implementation, especially during the “auto-exposure control”. The exposure control of this digital camera mimics a “shutter control” in a conventional film camera and does it automatically. During the course of “auto exposure control”, the camera controller-microprocessor determines the ambient light level from the video stream out of the sensor and determines whether to let the sensor be exposed to light for longer or shorter durations. To make the convergence timely and conveniently, it is very desirable to achieve the “exposure control” by changing just one parameter. The EPS304C does just that. The camera designers can program the “exposure time” continuously without keeping track the frame time or frame rate. When the users program the “exposure time” beyond the maximum time allowed by the preset frame rate, EPS304C automatically changes the frame rate immediately to accommodate the “exposure time”. However, EPS30C does it only when the user extends the exposure time beyond the maximum allowed by the user-preset frame rate without permanently changing those settings. Therefore, when the user drops the exposure time below the one consistent with the nominal video rate, everything goes back to normal.

Specifically, under low light condition, users can change the shutter time (by adjustment of the shutter timing registers described at Item 2 in the above list of registers in the section entitled “Programmable Registers”). This adjustment can be accomplished automatically by a processor outside the sensor but inside the camera unit that the sensor is a part of. For example, the camera processor can be programmed so that when the camera senses that the light level has dropped so much that sufficient exposure cannot be obtained (without undue amplification) at the preset video frame rate, the processor sends a digital signal to above timing registers changing the shutter timing as necessary to provide sufficient exposure. If the setting of the shutter timing registers produces a shutter time that is too long for the then set frame rate, the sensor is programmed to automatically decrease the frame rate to accommodate the longer shutter time. For example, if the master clock is at EPS304's maximum, 12 MHz with a frame rate of about 30 frames per second, and the user's camera processor calls for a doubling of the exposure time, then the sensor automatically causes the frame rate to drop to 15 frames per second. This feature allows EPS304 to be used under low light without changing master clock frequency or excessive circuit gain. The EPS304 is designed to achieve this effect without any interruption of video stream. When the camera programs the shutter time back to nominal values, the frame rate automatically goes back to 30 fps. A very important advantage of this feature is that an adequate exposure in low light levels is assured with the simple adjustment of a single parameter. No other sensor parameters need to be dealt with.

Applications

Applications of the Sensor Include:
PC and web cameras,
Video-conference cameras,
Surveillance and security cameras,
Automotive safety viewing cameras,
Machine vision and in-line control cameras,
Biometric security systems (i.e. fingerprint, palm and facial recognition), and
Toys, camcorder, and digital still cameras.

### Other Preferred Camera Features

Other camera features are required for utilizing the data out from sensor 100 as shown in FIG. 2 and converting this data into images. The additional features of a typical camera are described below.

Environmental Analyzer Circuits:

As shown in FIG. 2 the data out of the sensor section is preferably fed into an environmental data analyzer circuit 140 where image's statistics is calculated. The sensor region is partitioned into separate sub-regions, with the average or mean signal within the region being compared to the individual signals within that region in order to identify characteristics of the image data. For instance, the following characteristics of the lighting environment may be measured:
1. light source brightness at the image plane
2. light source spectral composition for white balance purpose
3. imaging object reflectance
4. imaging object reflectance spectrum
5. imaging object reflectance uniformity

The measured image characteristics are provided to decision and control circuits 144. The image data passing through environmental data analyzer circuit 140 are preferably not modified by it at all. In this embodiment, the statistics include the mean of the first primary color signal among all pixels, the mean of the second primary color signal, the mean of the third primary color signal and the mean of the luminance signal. This circuit will not alter the data in any way but calculates the statistics and passes the original data to image manipulation circuits 142. Other statistical information, such as maximum and minimum may be calculated as well. They can be useful in terms of telling the range of the object reflectance and lighting condition. The statistics for color information is on full image basis, but the statistics of luminance signal is on a per sub-image regions basis. This implementation permits the use of a weighted average to emphasize the importance of one selected sub-image, such as the center area.

Decision & Control Circuits:

The image parameter signals received from the environmental data analyzer circuit 140 are used by the decision and control circuits 144 to provide auto-exposure and auto-white-balance controls and to evaluate the quality of the image being sensed. Based on this evaluation, the control module (1) provides feedback to the sensor to change certain modifiable aspects of the image data provided by the sensor, and (2) provides control signals and parameters to image manipulation circuits 142. The change can be sub-image based or full-image based. Feedback from the control circuits 144 to the sensor 100 provides active control of the sensor elements in order to optimize the characteristics of the image data. Specifically, the feedback control provides the ability to program the sensor to change operation (or control parameters) of the sensor elements. The control signals and parameters provided to the image manipulation circuits 142 may include certain corrective changes to be made to the image data before outputting the data from the camera.

Image Manipulation Circuits:

Image manipulation circuit 142 receives the image data from the environmental analyzer 140 and, with consideration to the control signals received from the control module 144, provides an output image data signal in which the image data is optimized to parameters based on a control algorithm. In these circuits, pixel-by-pixel image data are processed so each pixel is represented by three color-primaries. Color saturation, color hue, contrast, brightness can be adjusted to achieve desirable image quality. The image manipulation circuits provide color interpolation between each pixel and adjacent pixels with color filters of the same kind so each pixel can be represented by three-color components. This provides enough information with respect to each pixel so that the sensor can mimic human perception with color information for each pixel. It further does color adjustment so the difference between the color response of sensors and human vision can be optimized.

Communication Protocol Circuits:

Communication protocol circuits 146 rearrange the image data received from image manipulation circuits to comply with communication protocols, either industrial standard or proprietary, needed for a down-stream device. The protocols can be in bit-serial or bit-parallel format. Preferably, communication protocol circuits 146 convert the process image data into luminance and chrominance components, such as described in the ITU-R BT.601-4 standard. With this data protocol, the output from the image chip can be readily used with other components in the market place. Other protocols may be used for specific applications.

Input & Output Interface Circuits:

Input and output interface circuits 148 receive data from the communication protocol circuits 146 and convert them into the electrical signals that can be detected and recognized by the down-stream device. In this preferred embodiment, the input & output Interface circuits 148 provide the circuitry to allow external components to get the data from the image chip, read and write information from/to the image chip's programmable parametric section.

Chip Package:

Image chip 100 is packaged into an 8 mm×8 mm plastic chip carrier with glass cover. Depending upon the economics and applications, other type and size of chip carrier can be used. Glass-cover can be replaced by other type of transparent materials as well. The glass cover can be coated with anti-reflectance coating, and/or infrared cut-off filter. In an alternative embodiment, this glass cover is not needed if the module is hermetically sealed with a substrate on which the image chip is mounted, and assembled in a high quality clean room with lens mount as the cover.

### Cell Phone Camera

The preferred image sensor described in detail in this application is designed to be used in a variety of camera units, especially camera units operable at video rates. Some features of one particular camera unit are shown in FIG. 1C. Lens 4 is based on a 1/4.5″ F/2.8 optical format and has a fixed focal length with a focus range of 1-5 meters. Because of the smaller chip size, the entire camera module can be less than 10 mm (Length)×10 mm (Width)×10 mm (Height). This is substantially smaller than the human eyeball! This compact module size is very suitable for providing a camera feature in portable appliances, such as cellular phone and personal digital assistants (PDA's). Lens mount 12 is made of black plastic to prevent light leak and internal reflectance. The image chip is inserted into the lens mount with unidirectional notches at four sides, so to provide a single unit once the image chip is inserted in and securely fastened. This module has metal leads on the 8 mm×8 mm chip carrier that can be soldered onto a typical electronics circuit board.

### Examples of Feedback & Control

Camera Exposure Control:

Sensor 100 as shown in FIG. 1C can be used as a photo-detector to determine the lighting condition. Since the sensor signal is directly proportional to the light sensed in each pixel, one can calibrate the camera to have a “nominal” signal under desirable light. When the signal is lower than the “nominal” value, it means that the ambient “lighting level” is lower than desirable. To bring the electrical signal back to “nominal” level, the pixel exposure time to light and/or the signal amplification factor in sensor or in the image manipulation module are automatically adjusted. The camera may be programmed to partition the full image into sub-regions is to be sure the change of operation can be made on a sub-region basis or to have the effect weighted more on a region of interest.

Camera White Balance Control:

The camera may be used under all kind of light sources. Light sources may have a variety of spectral distributions. As a result, the signal out of the sensor will vary depending on the spectral distribution of the light source. Images are typically displayed on a visualizing device, such as print paper or CRT display. Normally it is desirable to display the image as if it were illuminated by white light with a spectral distribution corresponding to sun light. Since the sensor has pixels covered with primary color filters, one can then determine the relative intensity of the light source from the image data. The environmental analyzer is to get the statistics of the image and determine the spectral composition and make necessary parametric adjustment in sensor operation or image manipulation to create a signal that can be displayed as if it were illuminated by sunlight.

### Crosstalk Reduction

The Problem

With the basic design of the present invention where the photodiode layers are continuous layers covering pixel electrodes, the potential for crosstalk between adjacent pixels is an issue. For example, when one of two adjacent pixels is illuminated with radiation that is much more intense than the radiation received by its neighbor, the electric potential difference between the surface electrode and the pixel electrode of the intensely radiated pixel will become substantially reduced as compared to its less illuminated neighbor. Therefore, there could be a tendency for charges generated in the intensely illuminated pixel to drift over to the neighbor's pixel electrode.

In the case of a three-transistor unit cell design, the photo-generated charge is collected on a capacitor at the unit cell. As these capacitors charge or discharge, the voltage at the pixel contact swings from the initial reset voltage to a higher voltage or lower voltage depending on the bias of the pixel circuits. A typical voltage swing is 1.4V. Due to the continuous nature of Applicant's coating, there is the potential for charge leakage between adjacent pixels when the sense nodes of those pixels are charged to different levels. For example, if a pixel is fully charged and an adjacent pixel is fully discharged, a voltage differential of 1.4V will exist between them. There is a need to isolate the sense nodes among pixels so crosstalk can be minimized or eliminated.

Gate-Biased Transistor

As explained in Applicant's parent patent application Ser. No. 10/072,637 (now U.S. Pat. No. 6,370,914) that has been incorporated herein by reference, a gate-biased transistor can be used to isolate the pixel sense nodes while maintaining all of the pixel electrodes at substantially equal potential so crosstalk is minimized or eliminated. However, an additional transistor in each pixel adds complexity to the pixel circuit and provides an additional means for pixel failure. Therefore, a less complicated means of reducing crosstalk is desirable.

Increased Resistivity in Bottom Photodiode Layer

Applicants have discovered that crosstalk between pixel electrodes can be significantly reduced or almost completely eliminated in preferred embodiments of the present invention through careful control of the design of the bottom photodiode layer without a need for a gate-biased transistor. The key elements necessary for the control of pixel crosstalk are the spacing between pixel contacts and the thickness and resistivity of the photodiode layers. These elements are simultaneously optimized to control the pixel crosstalk, while maintaining all other sensor performance parameters. The key issues related to each variation are described below.

1. Pixel Contact Spacing

Increased spacing, l, between pixel contacts increases the effective resistance between the pixels, as described in the relationship between resistance and resistivity.

$$R = ρ \frac{l}{t \cdot w} , \qquad ( Eq . 1 )$$

where “ρ” is the resistivity, “l” is the distance along the direction of electrical field, “t×w” represents the area of the cross section of the current flow.

The spacing between pixel contacts is a consequence of the designed pixel pitch and pixel contact area. From the geometric configuration alone, we can create a differentiation so carriers would favor one direction over the other. For example, along the vertical direction, the resistance becomes:
Rᵥ=ρ×T/(W×L),

where ρ is the resistivity, T is the thickness of the bottom photodiode layer making contact to the pixel electrode, W is the pixel width and L is the pixel length.

In most cases W=L, therefore, we can get
Rᵥ=ρ×T/W²

On the other hand, along the lateral direction, the resistance becomes
Rₗ=ρ/T, since see by the electrical current flow, the distance is L and the area of cross section is (L×T) now.

The resistance ratio between lateral and vertical is
Rₗ/Rᵥ=(W/T)²

This can create a preferred carrier flow direction, favorable in vertical direction, as long as W/T>1. In Applicants' practice, the layer (making contact to the pixel electrode, either P-layer or N-layer) thickness is around 0.01 urn and pixel width is about 5 um, W/T=500 which is much greater than 1. Of course, the final pixel contact size must be selected based on simultaneous optimization of all sensor performance parameters.

2. Layer Thickness

Decreasing the coating thickness, t, results in an increase in the effective inter-pixel resistance as described in equation 1. In the case of an amorphous silicon N-I-P diode, the layer in question is the bottom P-layer. In the case of an amorphous silicon P-I-N diode, it is the bottom N-layer. In both cases, only the bottom-doped layer is considered because the potential barriers that occur at the junctions with the I-layer prevent significant leakage of collected charge back into the I-layer. Also in both cases, there is a practical limit to the minimum layer thickness, beyond which the junction quality is degraded.

3. Resistivity of the Bottom Layer

The parameter in Equation 1 that allows the largest variation in the effective resistance is p, the resistivity of the bottom layer. Varying the chemical composition of the layer in question can vary this parameter over several orders of magnitude. In the case of the amorphous silicon N-layer and P-layer discussed above, the resistivity is controlled by alloying the doped amorphous silicon with carbon and/or varying the dopant concentration. The resulting doped P-layer or N-layer film can be fabricated with resistivity ranging from 100 ohm-cm to more than 10¹¹ ohm-cm. The incorporation of a very high-resistivity doped layer in an amorphous silicon photodiode might decreases the electric field strength within the I-layer, therefore whole sensor performance must be considered when optimizing the bottom doped layer resistivity. As indicated above increasing the resistivity of the bottom layer also avoids adverse electrical effects resulting form contact at the edge of the pixel array between the bottom layer 114 and the transparent electrode layer 108 as shown at 125 in FIGS. 9 and 10A.

The growth of a high-resistivity amorphous silicon based film can be achieved by alloying the silicon with another material resulting in a wider band gap and thus higher resistivity. It is also necessary that the alloyed material not act as a dopant providing free carriers within the alloy. Elements known to alloy well with amorphous silicon are germanium, tin, oxygen, nitrogen and carbon. Of these, alloys of germanium and tin result in a narrowed band gap and alloys of oxygen, nitrogen and carbon result in a widened band gap. Alloying of amorphous silicon with oxygen and nitrogen result in very resistive, insulating materials. However, silicon-carbon alloys allow controlled increase of resistivity as a function of the amount of incorporated carbon. Furthermore, silicon-carbon alloy can be doped both N-type and P-type by use of phosphorus and boron, respectively.

Amorphous silicon based films are typically grown by plasma enhanced chemical vapor deposition (PECVD). In this deposition process the film constituents are supplied through feedstock gasses that are decomposed by means of low-power plasma. Silane or di-silane are typically used for silicon feedstock gasses. The carbon for silicon-carbon alloys is typically provided through the use of methane gas, however ethylene, xylene, dimethyl-silane (DMS) and trimethyl-silane (TMS) have also been used to varying degrees of success. Doping may be introduced by means of phosphene or diborane gasses.

### Preferred Process for Making Photodiode Layers

In Applicants' current practice for a P-I-N diode, the N-layer, makes contact with the pixel electrode, has a thickness of about 0.01 microns. The pixel size is 5 microns×5 microns. Because of the aspect ratio between the thickness and pixel width (or length) is much smaller than 1, within the N-layer the resistance along the lateral (along the pixel width/length direction) is substantially higher than the resistance in the vertical direction, based upon Equation 1. Because of this, the electrical carriers prefer to flow in the vertical direction rather than in the lateral direction. This alone may not be sufficient to ensure that the crosstalk is low enough. Therefore, Applicants prefer to increase the resistivity by introducing carbon atoms into N-layer to make it become a wider band-gap material as described above. Applicants' preferred N-layer is a hydrogenated amorphous silicon layer with carbon concentration about 10²² atoms/cc. The hydrogen content in this layer is in the order of 10²¹-10²² atoms/cc, and the N-type impurity (Phosphine) concentration in the order of 10²⁰-10²¹ atoms/cc. This results in a film resistivity of about 10¹⁰ ohm-cm. For a 5 um×5 um pixel, we have found out that negligible pixel crosstalk can be achieved even when the N-layer resistivity is down to the range of a few 10⁶ ohm-cm. Like what is described above, there is a need of engineering trade-off among N-layer thickness, carbon concentration, boron concentration and pixel size to achieve the required overall sensor performance. Therefore, the resistivity requirement may vary for other pixel sizes and configurations. For this P-I-N diode with 5 um×5 um pixel, our I-layer is an intrinsic hydrogenated amorphous silicon with a thickness about 0.5-1 um. The P-layer is also a hydrogenated amorphous silicon layer with P-type impurity (Boron) concentration in the order of 10²⁰ to 10²¹ atoms/cc. Carbon atoms/molecules can be doped into the P-layer as well in order to make the band-gap wider and matching between P-layer and I-layer better leading to improvement of quantum efficiency and dark current leakage.

For applications where the polarity of the photodiode layers is reversed and the P-layer is adjacent to the pixel electrode, the carbon atoms/molecules are added to the P-layer to reduce crosstalk and to avoid adverse electrical effects at the edge of the pixel array.

### Avoiding Adverse Electrical Effects at Edge of Pixel Array

As explained above since Applicants use carbon in the bottom layer of the photodiode to make it very resistive. Therefore, contact of the bottom layer with top transparent electrode layer 108 at the edge of the pixel array as shown at 125 in FIGS. 10A and 10B does not affect the electrical properties of the photodiode as long as the electrical resistance, from the pixel electrode to the place where transparent electrode layer 108 makes contact to the bottom photodiode layer 114, is high enough. In preferred embodiments, the resistivity of the bottom layer (either n-type or p-type) is greater than 10⁶ ohm-cm. The thickness of this layer is about 0.01 um and the width of this layer is about 1 cm for Applicants 2 million pixel sensor with 5 um pixel pitch. The typical distance between the pixel electrodes near the edge of pixel array to the location where electrode layer 108 makes contact to the bottom photodiode layer 114 is greater than 0.01 cm; therefore, the resistance is greater than
10⁶ (ohm-cm)×0.01 cm (1 cm×10⁻⁶ cm)=1×10¹⁰ ohm

This is as resistive as most known insulators. As a result of, the image quality would not be affected.

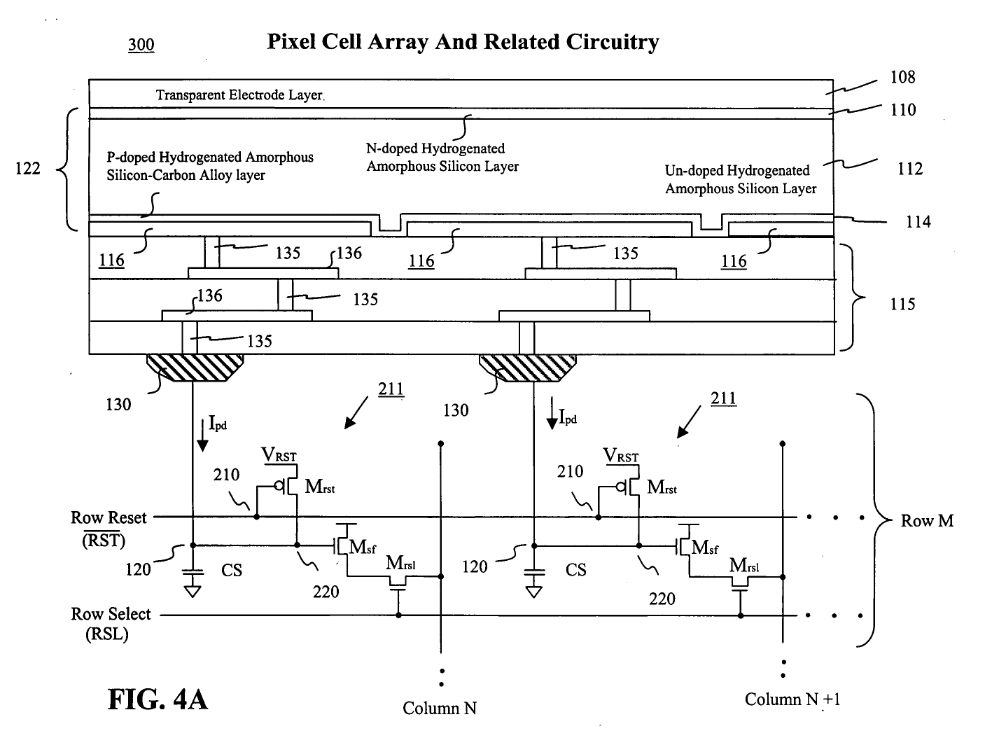

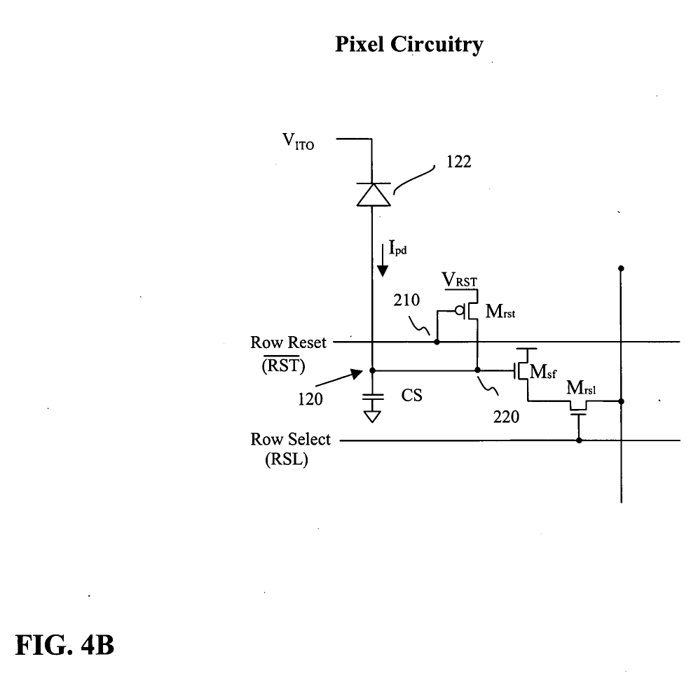

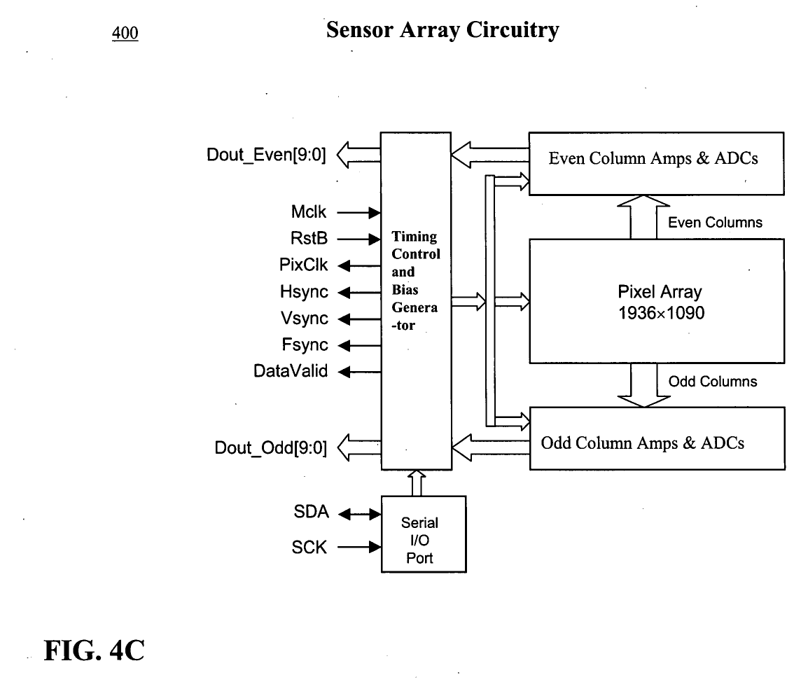

The photodiode layers of the present invention are laid down in situ without any photolithography/etch step in between. (Some prior art sensor fabrication processes incorporate a photolithography/etch step after laying down the bottom photodiode layer in order to prevent or minimize cross talk.) An important advantage of the present process is to avoid any contamination at the junction between the bottom and intrinsic layers of the photodiode that could result from this photolithography/etch step following-the laying down of the bottom layer. Contamination at this junction may result in electrical barrier that would prevent the photo-generated carriers being detected as electrical signal. Furthermore, it could trap charges so deep that the charges could not recombined with opposite thermally generated charges resulting in permanent damage to the sensor. Once the photodiode layers are put on the CMOS wafer, a photolithography/etch step is used to open up transparent electrode layer (TEL) contact pads and input/ output (I/O) bonding pads as shown at 127 and 129 in FIGS. 9 and 10A. These pads are preferably made of metal such as aluminum. The objective of this step is to remove the photodiode layers from the chip area 104 as shown in FIG. 2. Applicants do not want it to be covered by photodiode layers, including the areas for TEL contact pads and I/O bonding pads. Applicants' preferred approach is to have the photodiode layers cover the pixel array and extend out enough distance from each edge of the pixel array to avoid the adverse effect near the pixel array edges. As a result, the dimensions of the photodiode area when added to the dimensions of the gaps between two photodiode areas are much larger relative to the CMOS process circuit geometry; therefore, the precision of this photolithographic/etch step is considered non-critical. In the semiconductor industry, a non-critical photographic step requires much less expensive photolithographic mask and etch processes and can be easily implemented. Once Applicants open up the TEL contact pads and I/O bonding pads, Applicants then deposit a homogenous indium tin oxide layer onto the entire wafer. As a result of it, the inner surface of the TEL layer 108 makes physical and electrical contact to the TEL contact pad 127 as well as the top surface of layer 110 as shown in FIG. 4A and the edge of layers 112 and 114 of the photodiode layers, as shown in FIGS. 9 and 10A. Then Applicants go through another non-critical photolithography/etch step to open up the I/O bonding pads 129. The I/O bonding pads are wire-bonded onto an integrated circuit packaging carrier with appropriate leads. The leads of the integrated circuit packaging carrier are preferably used to make electrical contact to other electronic components on a printed circuit board of a camera or other instrument in which the sensor is to be installed. Through these I/O bonding pads and the TEL contact pads, the TEL layer 106 can be biased relative to electrodes 116 to a desirable voltage externally to create an electrical field across the photodiode layers to detect photon-generated charges.

Below is a summary of the special steps Applicants use to deposit the special photodiode layers on top of the active pixel of Applicants preferred sensors using a wafer based process:
Step 1: The CMOS process is no different from the basic CMOS art used in the integrated circuit industry. Applicants use a typical CMOS process to make the active pixel array circuitry and periphery circuitry of the sensor. The pixel electrode 116 is also made as a part of the typical CMOS process. The active pixel circuitry shown as 118 in FIG. 3A is described in more detail in FIGS. 3B and FIGS. 4A and 4B. The periphery circuitry of preferred embodiments is shown in FIGS. 2 and 10C. These integrated circuits can be standard CMOS sensor circuits regularly used in prior art sensors and well known in the sensor industry. As indicated in FIG. 4A pixel control and readout is provided by row reset, row select and column select signals directed to and from each pixel in order to read the output signal from each pixel and to reset the pixels for the next signal. Preferred periphery circuitry as shown in FIG. 2 in preferred embodiments provides the pixel and initial manipulation of the sensor output data as describe elsewhere in this specification.
Step 2: Applicants deposit hydrogenated amorphous the silicon (a-Si:H) photodiode layer, all three layers (n-i-p or p-i-n), using plasma-enhanced chemical vapor deposit (PECVD) techniques. Other techniques may be used as long as it produces good a-Si layers.
Step 3: Photolithography plus etch processes are used to open up the ITO contact pad and I/O bonding pads, and clear out the areas which we do not want to be covered with a-Si.
Step 4: Applicants deposit the transparent electrode (Indium Tin Oxide-ITO) layer 108 onto wafers using sputtering equipment. However, other techniques, even other materials, may be used to put on the TEL layer 108 as long as the thickness, optical and electrical properties are re-produced.
Step 5: Photolithography plus etch processes are used to open up the I/O bonding pads and clear away un-wanted ITO.
Step 6: Put on color filters.
Step 7: Photolithography processes again are used to open up the I/O bonding pads.
Step 8: Have the wafer diced.
Step 9: This sensor preferably is a component part of a video camera, cell phone of similar electronic instrument. The circuitry is mounted in an integrated circuit packaging carrier, wire-bonding selected bonding pads to corresponding leads of the IC carrier. These wire bonds in a preferred embodiment connect the I/O bonding pads to a lead for the application of pixel bias voltage and well as other leads for pixel readout and reset and for sensor control and for data manipulation as indicated in FIG. 2. For example, as indicated in FIG. 10D, Applicants Model EPS304C described below has 48 leads providing input and output between the sensor and other components in the unit of which the sensor is to be a component part. Not all of these 48 leads are utilized in preferred embodiments. Some of the ones that are utilized in a preferred sensor model (called Model EPS304C) to provide control function such as timing and synchronization are described in the section that follows and are referred to as “pins”.
Step 10: Seal the IC carrier with a glass cover, which is transmissive in the spectral range the sensor is used for.

Steps 2, 3, 4 and 5 in the order presented are special steps developed to fabricate POAP sensor and/or camera chips. The other listed steps are processes regularly used in integrated circuit sensor fabrication. Variations in these steps can be made based on established practices of different fabrication facilities.

### Variations

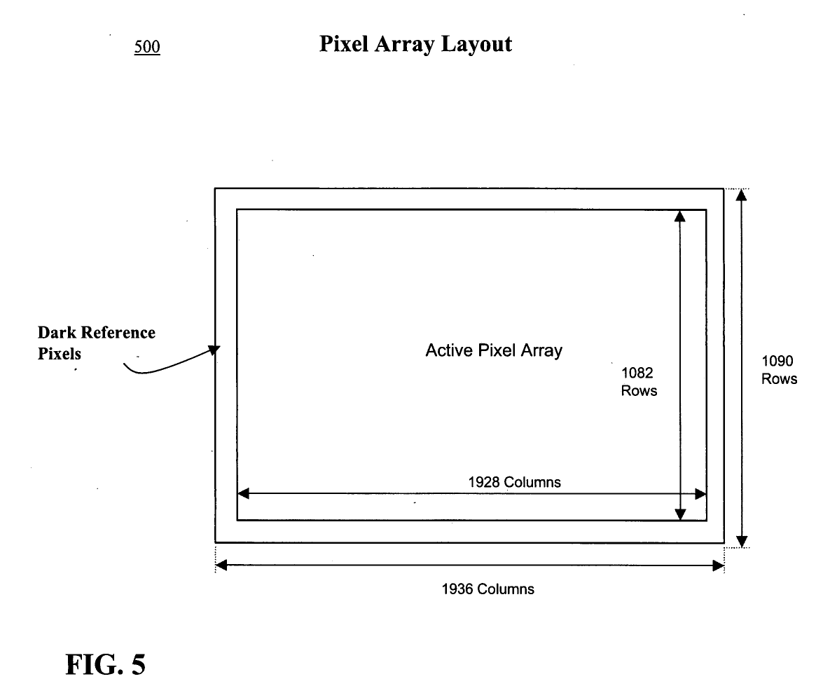

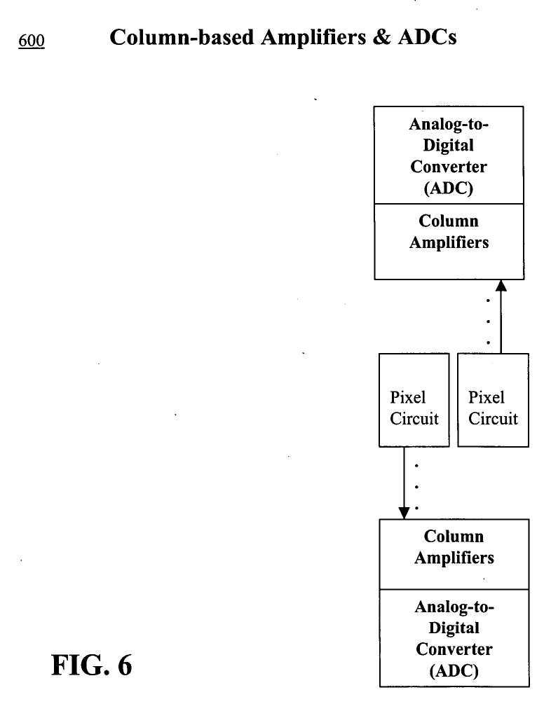

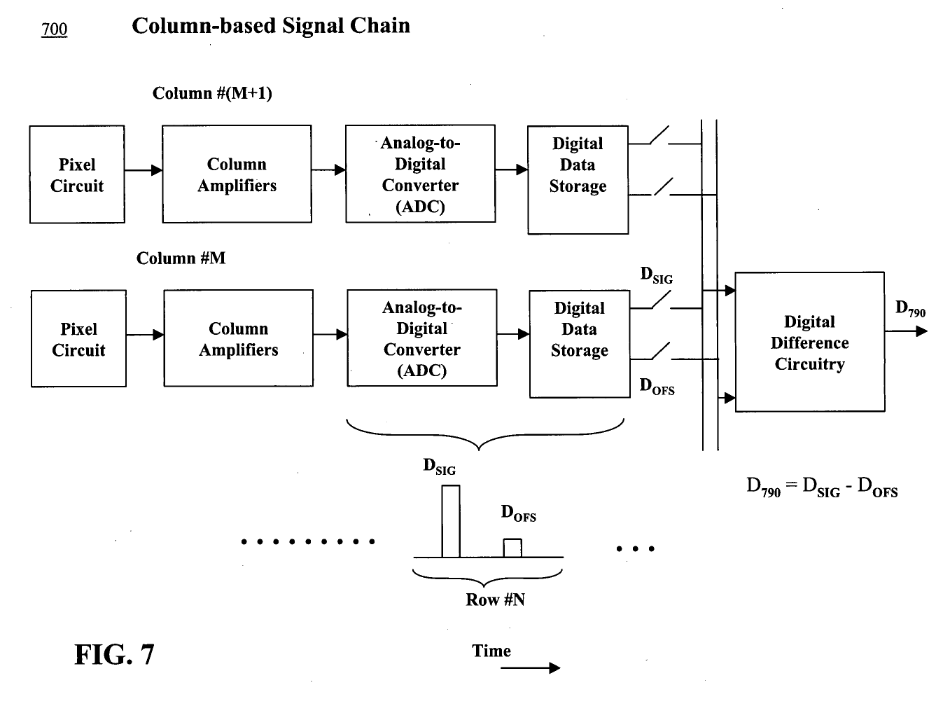

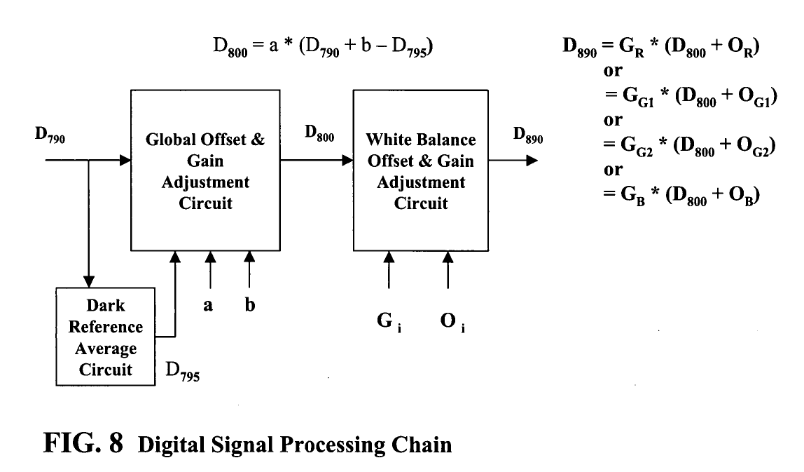

Preferred embodiments of the present invention have been described in detail above. However, many variations from that description may be made within the scope of the present invention. For example, the three-transistor pixel design described above could be replaced with more elaborate pixel circuits (including 4, 5 and 6 transistor designs) described in detail the parent applications. The additional transistors provide certain advantages as described in the referenced applications at the expense of some additional complication. The photoconductive layers described in detail above could be replaced with other electron-hole producing layers as described in the parent application or in the referenced '353 patent. The photodiode layer could be reversed so that the n-doped layer is on top and the p-doped layer is on the bottom in which case the charges would flow through the layers in the opposite direction. The transparent layer could be replaced with a grid of extremely thin conductors. The readout circuitry and the camera circuits 140-148 as shown in FIG. 2 could be located partially or entirely underneath the CMOS pixel array to produce an extremely tiny camera. The CMOS circuits could be replaced partially or entirely by MOS circuits. Some of the circuits 140-148 shown on FIG. 2 could be located on one or more chips other than the chip with the sensor array. For example, there may be cost advantages to separate the circuits 144 and 146 onto a separate chip or into a separate processor altogether. The number of pixels could be decreased below 0.3 mega-pixels or increased above 2 million almost without limit. FIGS. 4C-8 illustrate some of the implementations of a 2-million pixel sensor.

### Other Camera Applications

This invention provides a camera potentially very small in size, potentially very low in fabrication cost and potentially very high in quality. Naturally there will be some tradeoffs made among size, quality and cost, but with the high volume production costs in the range of a few dollars, a size measured in millimeters and image quality measured in mega-pixels or fractions of mega-pixels, the possible applications of the present invention are enormous. Some potential applications in addition to cell phone cameras are listed below:
Analog camcorders
Digital camcorders
Personal computer cameras
Endoscopes
Military unmanned aircraft, bombs and missiles
Sports
High definition television sensor

### Eyeball Camera

Since the camera can be made smaller than a human eyeball, one embodiment of the present invention is a camera fabricated in the shape of a human eyeball. Since the cost will be low the eyeball camera can be incorporated into many toys and novelty items. A cable may be attached as an optic nerve to take image data to a monitor such as a personal computer monitor. The eyeball camera can be incorporated into dolls or manikins and even equipped with rotational devices and a feedback circuit so that the eyeball could follow a moving feature in its field of view. Instead of the cable the image data could be transmitted wirelessly using cell phone technology.

### A Close-Up View of a Football Game

The small size of these cameras permits them along with a cell phone type transmitter to be worn (for example) by professional football players installed in their helmets. This way TV fans could see the action of professional football the way the players see it. In fact, the camera plus a transmitter could even be installed in the points of the football itself that could provide some very interesting action views. These are merely examples of thousands of potential applications for these tiny, inexpensive, high quality cameras.

While there have been shown what are presently considered to be preferred embodiments of the present invention, it will be apparent to those skilled in the art that various changes and modifications can be made herein without departing from the scope and spirit of the invention.

For example, the features such as on-chip black compensation, user-selectable timing master and slave mode and exposure time control can be used with sensors of all kinds of photo-sensing elements, not limited to Photodiode-On-Active-Pixel (POAP) technology. These other sensors include CCD image sensors. They can be used with the traditional CMOS sensors where photo-sensing element is made inside the silicon substrate and pixel circuitry is fabricated on the edge of the photo-sensitive region of the pixel. In the traditional CMOS active pixel sensors, the photo-sensing element can be formed by a simple p-n junction, a pinned diode with one side of the sensing element formed by a highly doped region and held by an external bias, or a gated-diode where one side of the photo-sensing element is formed by a thin poly-silicon gate held at an external bias.

Furthermore, features of this invention can be applied in cameras used without the lens to monitor the light intensity profile and output the change of intensity and profile. This is crucial in optical communication application where beam profile needs to be monitored for highest transmission efficiency. Certain features can be applied to extend light sensing beyond visible spectrum when the amorphous-Silicon is replaced with other light sensing materials. For example, one can use microcrystalline-Silicon to extend the light sensing toward near-infrared range. Such camera is well suitable for night vision. In the preferred embodiment, we use a package where senor is mounted onto a chip carrier on which is clicked onto a lens housing. One can also change the assembly sequence by solder the sensor onto a sensor board first, then put the lens holder with lens to cover the sensor and then mechanically fasten onto the PCB board to make a camera. This is a natural variation from this invention to those skilled in the art.

Thus, the scope of the invention is to be determined by the appended claims and their legal equivalents.

What is claimed is:

1. An electronic image sensor that can be adapted to operate at a predetermined normal frame rate or at frame rates lower than the predetermined normal frame rate, said sensor comprising:
A. an array of photo-sensing pixel elements for producing image frames, each pixel element defining a photo-sensing region of said sensor and each pixel element comprising:
1) charge collecting circuits for collecting electrical charges produced in the photo-sensing region, and
2) a charge storage element for the storage of the collected charges;
B. charge sensing circuits for sensing the collected charges;
C. charge-to-signal conversion elements for converting charge values to electronic signals; and
D. timing elements for controlling the pixel circuits to produce image frames based on a master clock signal at the predetermined normal frame rate, defining a normal maximum per frame time, said timing elements comprising:
1) exposure adjustment circuits for setting per frame exposure times within a range of exposure times that include exposure times substantially longer than said normal maximum per frame time,
2) frame rate adjustment circuits that can be adapted to permit a decrease of the predetermined normal frame rate without adjusting the master clock signal.

2. The sensor as in claim 1 wherein said predetermined normal frame rate is a video rate.

3. The sensor as in claim 2 wherein said predetermined normal frame rate is about 30 frames per second.

4. The sensor as in claim 2 wherein said predetermined normal frame rate is about 25 frames per second.

5. The sensor as in claim 1 wherein said exposure adjustment circuits are adapted to cause a decrease of frame rate below the predetermined normal frame rate only when necessary to accommodate an exposure time longer than the normal maximum per frame exposure time.

6. The sensor as in claim 1 wherein normal video frame rate is determined by a master clock frequency signal divided by the product of two predetermined default numbers representing: (1) a maximum number of rows of pixels and (2) a maximum number of columns of pixels.

7. The sensor as in claim 6 wherein number representing said maximum number of rows of pixels is 508 and said number representing said maximum number of columns of pixels is 782 and both of these numbers are set in a fabrication process.

8. The sensor as in claim 7 wherein the clock frequency signal is about 12 MHz, the normal frame rate is about 30.2 frames per second and the normal maximum per frame exposure time is about 33 milliseconds.

9. The sensor as in claim 1 wherein the sensor is a component of a camera system comprising a processor programmed to determine a charge collection time period, defining a shutter time, within a larger predetermined time period of at least one second, so as to achieve desired charge collection in the pixels within a desired range of charges.

10. The sensor as in claim 9 wherein said the larger predetermined time period is at least one second.

11. The sensor as in claim 9 wherein said exposure adjustment circuits are adapted to decrease the frame rate to produce a new per frame exposure time if the determined shutter time is greater than the normal maximum per frame exposure time, so that the new per frame exposure time is at least as long as the shutter time.

12. The sensor as in claim 11 wherein the new per frame is established utilizing a calculated number representing a maximum number of rows of pixels that is different from and is used in lieu of the predetermined default number representing the maximum number of rows of pixels so that the per frame exposure time is at least as long as the desired shutter time.

13. The sensor as in claim 11 wherein the new per frame is established utilizing a calculated number representing a maximum number of columns of pixels that is different from and is used in lieu of the predetermined default number representing the maximum number of columns of pixels so that the per frame exposure time is at least as long as the desired shutter time.

14. The sensor as in claim 1 wherein said image sensor is a CMOS image sensor.

15. The sensor as in claim 1 wherein said image sensor is a CCD image sensor.

16. The sensor as in claim 1 wherein the photo sensing region and the said electrical circuitry for each pixel are fabricated on or into a single substrate.

17. The sensor as in claim 1 wherein said photo sensing region of each pixel is a portion of a single multi-layer photo diode layer covering each pixel.

18. The sensor as in claim 1 wherein said electrical circuitry for each pixel is fabricated adjacent to but not under the photo-sensitive region of the pixel.

19. The sensor as in claim 1 wherein said sensor is a part of a monolithic camera integrated circuit comprising additional CMOS circuits including an Analog-to Digital circuit and at least one digital processor

20. The sensor as in claim 1 and further comprising on-chip black compensation circuit.

21. The sensor as in claim 20 wherein said on-chip black compensation is programmed to utilize signals from at least one pixel covered with a opaque material to provide a reference signal for black compensation.

22. The sensor as in claim 1 and further comprising a user-selectable timing master and slave mode.

23. The sensor as in claim 1 wherein said sensor is adapted for utilization in any of a plurality of electronic devices.

24. The sensor as in claim 23 wherein said plurality of electronic devices includes electronic device chosen from the following group of electronic devices:
personal computers with web cameras,
video-conference cameras,
surveillance and security electronic cameras,
automotive safety viewing electronic cameras,
machine vision and in-line control electronic cameras,
electronic biometric security systems,
electronic toys,
camcorder,
digital still cameras,
endoscopes,
unmanned aircraft,
unmanned bombs,
unmanned missiles
sports equipment, and
high definition television cameras.

25. The sensor as in claim 1 wherein charge-sensing circuits are provided and are configured to provide two signals for each pixel to reduce fixed pattern noise.

26. The sensor as in claim 25 wherein one of said signals represents pixel signals and the other one represents a reference signal.

27. The sensor as in claim 25 wherein the difference of the two said signals represents the true signal.

28. The sensor as in claim 19 wherein said Analog-to-Digital circuit is configured with a Column-Parallel architecture with one Analog-to-Digital circuit in each column.

29. The sensor as in claim 28 wherein additional circuits are provided and are configured to provide two analog-to-digital conversions for each pixel to reduce fixed pattern noise.

30. The sensor as in claim 1 where said sensor wherein said array of pixels define odd and even columns each with top and bottom sides and further comprising two data output paths from the top and bottom sides of the said array representing video output from even columns and odd columns respectively.

31. The sensor as in claim 30 where said two data output ports are interleaved to form a pixel-sequential video stream with one single data output to external.

32. The sensor as in claim 1 wherein a plurality of pixel elements in said array of pixel elements are covered with an opaque visible light shield and are adapted to operate as dark references.

33. The sensor as in claim 32 wherein said dark references is subtracted from a video signal before output to external.

34. The sensor as in claim 1 and further comprising an array of color filters located on top of said pixels.

35. The sensor as in claim 34 wherein said color filters are comprised of red, green and blue filters arranged in four color quadrants of two green, one red and one blue.

36. The sensor as in claim 34 and further comprising a gain adjustment circuit to produce white-balanced signals under various light sources.

37. The sensor as in claim 1 and also comprising image manipulation circuits fabricated on and into said substrate.

38. The sensor as in claim 1 and also comprising data analyzing circuits fabricated on and into said substrate.

39. The sensor as in claim 1 and also comprising input and output interface circuits fabricated on and into said substrate.

40. The sensor as in claim 1 and also comprising decision and control circuits fabricated on and into said substrate.

41. The sensor as in claim 1 and also comprising communication circuits fabricated on and into said substrate.

42. The sensor as in claim 1 wherein said sensor is an integral part of a camera attached by a cable to a cellular phone.

43. The sensor as in claim 1 wherein said sensor in an integral part of a camera in a cellular phone.

44. The sensor as in claim 1 wherein said array is a part of a camera fabricated in to form of a human eyeball.

45. The sensor as in claim 19 wherein said monolithic camera integrated circuit further comprises decision and control circuits adapted to analyze pixel data, and based on that data, controlling signal output from said sensor array.

46. The sensor as in claim 45 wherein said at least one processor is adapted to control signal output by adjusting signal amplification.

47. The sensor as in claim 1 and further comprising CMOS timing circuits permitting the sensor to function as a timing master or a timing slave.

48. The sensor as in claim 1 wherein said plurality of pixel circuits is at least 0.1 million-pixel circuits.
